(19) United States
(12) Patent Application Publication
(10) Pub. No.: US 2026/0221977 A1
(43) Pub. Date: Jul. 30, 2026

(54) FREQUENCY-STABLE, LOW-NOISE TIMING SIGNAL GENERATOR HAVING MULTIPLE MEMS RESONATORS AND NESTED-PLL STRUCTURE

(71) Applicant: SiTime Corporation, Santa Clara, CA (US)

(72) Inventors: Sassan Tabatabaei, Sunnyvale, CA (US); Raj-Kumar Palwai, Fremont, CA (US); Masato Yamaguchi, Inagi City (JP); Ugur Sönmez, Den Haag (NL); Aaron Partridge, Cupertino, CA (US)

(21) Appl. No.: 19/145,991

(22) PCT Filed: Jan. 25, 2024
(86) PCT No.: PCT/US2024/012909

§ 371 Date: Jul. 7, 2025

Related U.S. Application Data
(60) Provisional application No. 63/441,917, filed on Jan. 30, 2023.

(51) Int. Cl. H03L 7/099; G01K 7/32; H03L 7/08

(52) U.S. Cl. CPC H03L 7/0991; G01K 7/32; H03L 7/0805

(57) ABSTRACT

A frequency synthesizer uses an oven-controlled oscillator (“OCXO”) to generate a reference signal. A nested-PLL structure features an outer PLL loop with a divider that implements temperature correction of the output of the OCXO, to thereby form a temperature-compensated OCXO (“TCOCXO”); this divider also is dependent on information that selects a frequency for synthesis. An oscillation source of the outer PLL loop is implemented as an inner PLL loop of the nested-PLL structure; this inner PLL loop use an output of a second oscillator (“SXO”) as its reference frequency and an electronic VCO. The nested-PLL structure is designed such that phase noise from the TCOCXO dominates a synthesized frequency output for low frequencies, phase noise from the SXO dominates at mid-range frequencies, and phase noise from the electronic VCO dominates at high frequencies.

### REFERENCE TO RELATED APPLICATIONS

This patent application is filed under 35 USC § 371 as a national stage filing of Patent Cooperation Treaty Application No. PCT/US2024/012909, published as WO 2024163248, and internationally filed on Jan. 25, 2024, which in turn claims the benefit of U.S. Provisional Patent Application No. 63/441,917, filed Jan. 30, 2023, for “frequency-stable, low-noise timing signal generator having multiple MEMS resonators and nested-PLL structure;” each aforementioned patent application is hereby incorporated by reference.

### TECHNICAL FIELD

This disclosure relates to timing signal generators suitable for use with high frequency applications. More particularly, this disclosure relates to architectures for a high frequency timing signal generator based on the use of multiple MEMS resonators and a cascade PLL structure. The structures provided by this disclosure are especially useful for frequency synthesizer and/or clock generator applications.

### BACKGROUND

Timing signal generators are ubiquitous to all digital electronic devices. Well-known circuit designs are typically based on some type of resonator and a phase-locked loop (“PLL”).

A typical PLL operates with a reference signal having an input frequency, a phase detector, some type of controllable oscillator (typically a voltage controlled oscillator, or “VCO”) and a feedback path to the phase detector. Many PLL designs, particularly those that generate timing outputs different than the reference signal, also have feature some type of divider or multiplier in the feedback path; such a divider or multiplier will simply be referred to herein as a “divider,” i.e., denoting some type of numerical adjustment, fractional or otherwise, of the reference signal). The PLL attempts to lock oscillations of a signal from the divider (or from VCO, if no divider is present) to oscillations of the reference signal; the divider operates much like a gear, e.g., causing the VCO to operate slower or faster than the input frequency, i.e., until a frequency-scaled version of the VCO output tracks the reference signal. This scaling effectively causes the VCO to generate an output signal as desired, e.g., having a frequency that is scaled according to how the divider is used. Generally speaking, a PLL passes phase noise from the reference signal up to an output frequency corresponding to the PLL's loop rate, and then, at higher frequencies, phase noise from the reference signal is lost and phase noise of the VCO dominates the PLL's output. This basic design operate well for many conventional applications and can be used to generate timing signals of much greater frequency than the input frequency; for example, if the divider in the PLL's feedback path reduces the frequency of the signal from the VCO by “eight,” the effect is to cause drive the VCO to produce a frequency that is “eight” times that of the reference signal.

However, as processor clock speeds and signaling rates continue to increase, the need for generation of correspondingly fast, precise timing signals creates substantial design challenges, as the phase noise/frequency stability of the PLL's output becomes a much more significant problem; this is to say, with high frequencies (e.g., gigahertz frequencies and beyond), and with frequencies associated sub-nanosecond clock periods, phase noise that would have been acceptable at much lower frequencies is no longer acceptable, and can swamp timing margin. Of note, many new electronic devices require generation of not just one, but typically many timing signals having different phase and frequency characteristics. As but one example, fifth generation (“5G”) mobile communication devices typically need multi-gigahertz clocks, as well as timing signals to support radio frequency (“RF”), wireless local area network (“WLAN”), cellular, Bluetooth, and other modems, used for various types of communication formats. This requirement further complicates design of timing signal generators, e.g., a timing signal generator that may have acceptable phase noise/frequency stability for high frequency applications may perform poorly when applied to low frequency tasks, and conversely, a timing signal generator that may have acceptable phase noise/frequency stability for low frequency applications may perform poorly when applied to high frequency tasks. Simply stated, the evolution of digital devices is such that the many existing timing generator designs (e.g., based on the conventional, single-PLL-based approach) generally lack the required precision, e.g., they cannot operate without unacceptable levels of signal noise and/or levels of frequency stability, given the typical requirements of the newer generations of digital device technologies.

What is needed is a set of techniques for addressing these problems. More specifically, what is needed is a set of techniques for building timing signal generators with improved frequency stability that can meet demands associated with very high frequency timing signal generation (i.e., especially at gigahertz frequencies), and which also support the needs of these newer digital devices (e.g., 5G devices). Ideally, such techniques would provide tools to support effective design of a frequency synthesizer/clock generator that can support a wide range of timing signal requirements of newer digital devices, providing for stable clock and other timing signal generation throughout an entire frequency range of interest, e.g., from very low to very high frequencies. The present invention addresses these needs and provides further, related advantages.

### BRIEF DESCRIPTION OF THE DRAWINGS

FIG. 1 is an illustrative diagram used to explain one embodiment 101 of a timing signal generator.

FIG. 2A is a block diagram used to explain an embodiment 201 that relies on multiple PLLs, denoted in the FIG. as PLL-1, PLL-2, PLL-3, and so on, through PLL-k.

FIG. 2B is a graph 251 that is used to discuss the use of multiple PLLs in the context of embodiments described herein.

FIG. 3A is an illustrative diagram used to explain one embodiment 101 of a timing signal generator.

FIG. 3B is a graph 331 that is used to discuss phase noise/frequency stability, and how some embodiments can be designed so as to yield lower phase noise across a wider range of output frequencies.

FIG. 3C is block diagram of one embodiment 351 of a timing signal generator.

FIG. 4A is an illustrative diagram showing another embodiment 401 of a timing signal generator.

FIG. 4B is an illustrative diagram showing another embodiment 421 of a timing signal generator.

FIG. 4C is an illustrative diagram showing another embodiment 431 of a timing signal generator.

FIG. 4D is an illustrative diagram showing another embodiment 441 of a timing signal generator.

FIG. 4E is an illustrative diagram showing another embodiment 451 of a timing signal generator.

FIG. 5A is a block diagram showing one embodiment of an oven-controlled oscillator (“OCXO”).

FIG. 5B is a block diagram showing the use of two MEMS resonators to provide for a temperature-compensated oscillator (“TCXO”) design.

FIG. 5C is a block diagram showing an embodiment of temperature-compensated, oven-controlled oscillator (“TCOCXO”) which is rooted in the use of two MEMS resonators.

FIG. 6 shows a more detailed embodiment 601 of a frequency-stable, low-noise timing signal generator having multiple MEMS resonators and a nested-PLL structure.

FIG. 7A is a block diagram of an embodiment 701 with various types of frequency scaling options.

FIG. 7B is a block diagram of one embodiment 751 that uses open-loop digital frequency synthesis (“DDS”), e.g., with input 763 being used to control frequency selection, i.e., such that one or more downstream PLLs 755 and/or 761 pass phase noise of a DDS circuit 753 below a loop rate of the PLLs and pass phase noise of a LCXO for high frequencies.

The subject matter defined by the enumerated claims may be better understood by referring to the following detailed description, which should be read in conjunction with the accompanying drawings. This description of one or more particular embodiments, set out below to enable one to build and use various implementations of the technology set forth by the claims, is not intended to limit the enumerated claims, but to exemplify their application. Without limiting the foregoing, this disclosure provides several different examples of techniques for building low-noise, frequency-stable timing generators. In specific embodiments, these timing signal generators can be implemented as frequency synthesizers/clock generator circuits which produce highly stable timing signals at a wide range of frequencies suitable for newer digital devices, e.g., devices fully compatible with the 5G mobile computing requirements. Specific die/package configurations are also shown. While specific examples are presented, the principles described herein may also be applied to other methods, devices and systems as well.

### DETAILED DESCRIPTION

This disclosure provides techniques for addressing the aforementioned problems.

In one embodiment, a timing signal generator uses multiple phase-locked-loops (“PLLs”) that can be used to switch between several oscillation sources depending on a frequency to be generated. For example, in the context of a frequency synthesis circuit, an input can be received that defines a frequency of interest that is to be generated. A first PLL causes a performance parameter associated with a first oscillation source to dominate an output depending on frequency of a timing signal that is to be generated; for frequencies exceeding a loop rate of the first PLL, the performance parameter associated with a first voltage controlled oscillator (“VCO”) associated with the first PLL then dominate the output. A second PLL is used to cause a second oscillation source to dominate an output depending on frequency of a timing signal to be generated; for frequencies exceeding a loop rate of the second PLL, the performance parameter associated with a second VCO associated with the second PLL then dominate its output. These first and second PLLs can be used in series, parallel, cascaded, nested or other relationship. In a nested relationship for example, the second PLL is used to implement the VCO of the first PLL and to effectuate control over the VCO for the first PLL, with the loop rate of the second PLL consequently being used to cause phase noise to track a second oscillation source or a third oscillation source above the loop rate of the first PLL; this is to say, such an embodiment can have three or more oscillation sources used to generate a timing signal output and to effective improve overall phase noise characteristics by causing the timing signal output to emulate phase noise of whichever oscillator is best adapted to the timing signal frequency being generated. Generally speaking, in alternate embodiments (e.g., for situations where the performance parameter of interest is something other than lowest phase noise), a cascaded, series, parallel, nested, or other multi-PLL structure can be used to effectively select an oscillation source and/or cause an oscillation source to dominate an output, once again, dependent on the timing signal frequency being generated. Naturally, any number of PLLs and oscillation sources can be used, e.g., the techniques described herein are not limited to use of two PLLs, nor any specific number of oscillation sources. In some embodiments, one or more oscillation sources can be received which are in the form of an externally-provided frequency reference signal.

In a specific embodiment, a nested-PLL structure can be used to effectively select between multiple oscillation sources according to which oscillation source provides the lowest phase noise given frequency of a timing signal being generated. A timing signal generator uses a first oscillator (“FXO”) to provide for stable generation of a first reference signal. A nested-phase-locked-loop (“PLL”) structure is used to provide multiplication/division of a baseline frequency, such that a timing signal having a desired frequency can be generated. The nested-PLL structure comprises at least an outermost PLL loop and an innermost PLL loop of the nested-PLL structure. The first of these PLLs, i.e., the outermost PLL loop, receives the reference frequency from the FXO and locks a signal generated by a first variable oscillation source to this reference frequency; the first PLL can include a multiplier/divider (e.g., integer, fractional or otherwise) so as to scale the reference frequency (e.g., to generate a much higher frequency than the reference frequency in some applications). Optionally, the FXO can be rooted in an oven-controlled oscillator (“OCXO”) design or a temperature-controlled oscillator (“TCXO”) design, or both (“TCOXCO”); note that these variations are not required for all embodiments and, in some embodiments, the FXO can be rooted in an external frequency reference, or any type of conventional oscillator (e.g., a microelectromechanical systems or “MEMS” oscillator, a quartz oscillator, an LC oscillator, a closed loop frequency generator, a phase mixer or interpolator, an open-loop frequency generator, or indeed, any other conventional timing signal generator or circuit). In some embodiments, an open-loop digital frequency generator can be used for the FXO (e.g., an open-loop direct digital synthesis or “DDS” device, or a digital phase mixer or interpolator). A second PLL loop, i.e., an inner PLL loop in this case, serves in place of the VCO of the outer PLL loop, and itself receives a second reference signal from a second oscillator (“SXO”), to which it locks a second controlled oscillation source. Optionally, here also, this SXO can be any of the aforementioned oscillator or frequency generator types, e.g., an oven-controlled oscillator (“OCXO”) design or a temperature-controlled oscillator (“TCXO”) design, or both (“TCOXCO”), and so forth; these variations are also not required for all embodiments. The second variable oscillation source can be dependent on an electronic voltage controlled oscillator (“VCO”), i.e., it can be directly dependent on an electronic VCO or it can lock a signal from a further inner loop of the nested-PLL structure. In a specific application, the timing signal generator can be a frequency synthesizer and/or clock generator circuit, e.g., the mentioned divider of the first PLL loop can perform frequency scaling on a programmable basis, so as to generate a range of different output frequencies. The second PLL loop can also have a divider, which can be controlled based on a VCO control signal generated by the first PLL loop. The design of the timing signal generator, advantageously, is such that frequency stability is maintained and/or improved throughout a very wide range of output frequencies.

Note that one of more resonators of the FXO and/or the SXO (or other, further-order oscillator or oscillators) can optionally be implemented using one or more microelectromechanical systems (“MEMS”) resonators. Similarly, while PLLs are specifically referenced herein, the term “PLL” should be understood to generally encompass any type of locked-loop or similar feedback circuit including without limitation delay-locked-loops, inverter chains, phase-locked loops, fractional or integer multiplication loops and other types of digital or analog feedback circuits conventionally used for phase or frequency adjustment.

In one specific embodiment, extremely stable frequency generation can be obtained by further implementing a TCXO, OCXO or TCOCXO design for the FXO. Still more particularly, in one optional case, a TCOCXO is used. This is to say, in addition to maintaining a resonator of an OCXO at a constant temperature, an output frequency signal of the OCXO in some embodiments is also further temperature-compensated, providing for an ultra-stable oscillating reference signal. In some embodiments, the design of the TCOCXO can be configured to provide sub-parts-per-billion (“PPB”) variation in frequency per degree of temperature change (e.g., per degree change, Celsius). Combination of these features (e.g., oven control to maintain a resonator at a temperature, together with further temperature compensation of ovenized resonator output) facilitates provision, in some embodiments, of stable frequency synthesis throughout a very wide range of interest, e.g., from sub-hertz through tens of gigahertz.

Other embodiments feature placement of some or all of the structures introduced in this disclosure on specific dies of a packaged or unpackaged electronic device (e.g., a timing signal generator, frequency synthesizer and/or clock generator). Some of these designs promote a compact footprint and/or specific level of integration, for example, permitting a single “circuits” die to support, on a combined basis PLL circuitry, MEMS sustaining and/or sense circuitry, oven control circuitry, clock conditioning circuits, and/or any other permutation and/or combination of these components. For example, one embodiment features a die stack or other multi-die arrangement that places one or more MEMS resonator dies, encompassing both FXO and SXO resonators, in compact juxtaposition with one or more circuits dies. These dies optionally include on-board generation of all pertinent timing signals, e.g., and do not use an external oscillation source as one of multiple oscillation sources that can be effectively selected. In such an embodiment, the circuit dies can provide circuitry support both for oscillator functions (e.g., driving and/or processing output of the FXO and the SXO) as well as the nested-PLL structure described above. As a further example, in one contemplated embodiment, all such support circuitry can optionally be placed on a single CMOS or BiCMOS “circuits die.”

In some embodiments, each oscillator (e.g., FXO or SXO, and/or oscillators at another level loop in a nested-PLL hierarchy) can itself have two or more MEMS resonators, e.g., for reference frequency generation, temperature detection and/or some other purposes.

Other combinations and permutations of the structures described herein are contemplated as embodiments of the techniques described herein, although not individually and uniquely illustrated by a single, dedicated figure in the attached FIGS. Further features and advantages, and related structural alternatives, will be further apparent to those having ordinary skill in the art based on additional description which follows.

With the principle components of an improved timing signal generator thus introduced, this disclosure will proceed to discuss additional structures and related techniques, in greater detail.

Prior to proceeding to this additional description, however, it would be helpful to first discuss several specific terms. Firstly, it should be understood that contemplated embodiments can include “hardware logic,” “circuits” or “circuitry” (each meaning one or more electronic circuits). Generally speaking, and unless otherwise specified, these terms can include analog and/or digital circuitry, and can be, in nature, special purpose or general purpose. For example, as used herein, the term “circuitry” for performing a particular function can include one or more electronic circuits that are either “hard-wired” or are configurable circuits to perform the stated function (i.e., in some cases without assistance of instructional logic), and the term can include a microcontroller, microprocessor, FPGA or other form of processor which is general in design but which runs software or firmware (e.g., instructional logic) that causes or configures general circuitry (e.g., configures or directs a circuit processor) to perform the particular function. Note that as these statements imply, “circuits” and “circuitry” for one purpose are not necessarily mutually-exclusive to “circuits” or “circuitry” for another purpose, e.g., such terms indicate that one or more circuits are configured to perform a function, and one, two, or even all circuits can be shared with “circuitry” to perform another function (indeed, such is often the case where the “circuitry” includes a processor); this is to say, “circuitry to perform (function X)” and “circuitry to perform (function Y)” can encompass exactly the same circuitry or respective circuits, depending on implementation. Related to these points, the term “logic” can encompass hardware logic, instructional logic, or both, unless otherwise specified. Instructional logic can be code written or designed in a manner that has certain structure (architectural features) such that, when the code is ultimately executed, the code causes the one or more general purpose machines (e.g., a processor, computer or other machine) each to behave as a special purpose machine, having structure that performs, upon occurrence of defined events, described tasks with respect to processing operands, or else take specific actions or produce specific outputs. Generally speaking, circuits and/or processes described herein can, in some embodiments, be implemented as instructional logic (e.g., as instructions stored on non-transitory machine-readable media or other software logic), as hardware logic, or as any combination or permutation of these things, depending on embodiment or specific design. In connection with various embodiments herein, the term “device” is used to refer to an electronic product (e.g., based in, but not limited to, a chip, system, or board) with circuitry and possibly, but not necessarily, resident software or firmware; examples of a device include, without limitation, an end consumer product, a computer, a smart phone, an integrated circuit, a die, an electronic board, and/or other manifestations. “Non-transitory,” to the extent used herein, refers to any tangible (i.e., physical structure) medium or mediums, irrespective of the type of technology used to express data on that medium and irrespective of the format of data storage; for example, in one case, a particular expression can be optically stored on physical media, and in another case, the particular expression can be magnetically stored on physical media. Thus, when applied to storage and/or computer-readable and/or machine-readable subject matter, the term “non-transitory” indicates that data and/or instructions can be stored on such a physical structure storage medium using optical, magnetic, electronic, resistive and/or other storage formats/technologies, i.e., where some type of physical device, including without limitation, random access memory, hard disk memory, optical memory, a floppy disk, a compact disk (“CD”), a solid state drive (“SSD”), server storage, volatile memory, and/or nonvolatile memory, i.e., a physical thing, is used as the storage medium. Each such medium and/or device can be in standalone form (e.g., a program disk or solid state device) or embodied as part of a larger mechanism, for example, resident memory that is part of an electronic device such as a smart phone, computer, digital television, automobile, portable device, chip-card, dongle, server, printer, etc., or embodied as one or more such devices. “Instructions” can be implemented in different formats, depending on embodiment; for example, instructions can take form as metadata that when called is effective to invoke a certain action, as Java code or web scripting, as code written in a specific programming language (e.g., as C++ code), as a processor-specific instruction set, or in some other form. Depending on design, the instructions can also be executed by the same processor, different processors or processor cores, FPGAs or other configurable circuits, for example, being adapted for execution by a single computer in some cases, and in other cases, being adapted for execution on a distributed basis, e.g., using one or more servers, web clients, or application-specific devices, not necessarily all operating at the same time. The term “integrated circuit” (or “IC”) typically refers to a structure having at least one die, packaged or otherwise, and, as implied, a single IC and/or die can also be a type of electronic device. The term “MEMS” refers to electromechanical structures that are used at and/or operate at the circuit board, die, IC or similar level, regardless of whether such are characterizes as “miniature,” “micro,” “nano,” or otherwise in terms of scale. “Substrate” as used herein refers to any structure that is conventionally used to support an electronic circuit and/or electronic device, e.g., this term can include a wafer, a die, a lead frame, silicon offsets or pillars, a ceramic support, an IC or some other structure that can act as a support for these or the other elements described herein; a substrate typically but not necessarily also provides electrical routing and connection to the supported element(s). “Divider” and “multiplier,” unless otherwise specifically indicated, are used herein in a manner that is synonymous, e.g., to refer to frequency increase and/or reduction of an oscillating signal by any one of a number of structures in a feedback path of a PLL loop, whether integer-based, fractional, programmable or otherwise. As noted earlier, the term “PLL” should be taken, unless indicated to the contrary, to generally encompass any locked-loop structure used for timing control, including by way of example, delay-locked loops and other structures, and unless otherwise indicated, can take forms of digital or analog structures, and irrespective of whether specific conventional circuit structures (e.g., XOR gate as a phase detector) are used. The terms “PLL” and “PLL loop” and “locked-loop circuit” will generally be used in this disclosure as synonyms. The term “VCO” as used herein refers to any controllable oscillator, e.g., whether current controlled, voltage controlled, analog, digital or otherwise, e.g., it refers to an oscillation source that produces a variable frequency as part of a timing signal adjusted by a PLL to lock to phase and frequency of a reference frequency.

The meaning of other terms used herein should be clear based on context. Note that, to the extent that any document is incorporated herein by reference, the definitions of this document should be understood to predominate over any inconsistent definitions provided by such incorporated-by-reference documents. It is emphasized that the various elements discussed above or below, in any embodiment, can be used in any desired permutation or combination, in the same or in any other embodiment, with all such permutations and combinations being expressly contemplated by this disclosure. Selection and/or omission of structures for any given design or application is within the level of ordinary skill in the art, and none of the elements/structures discussed below are to be deemed “essential” for any purpose or function.

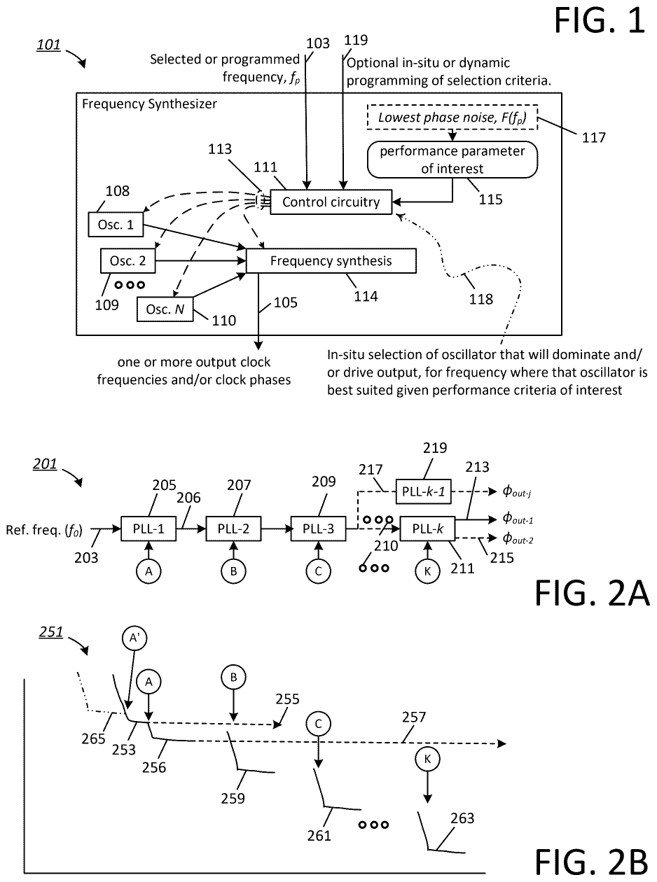

FIG. 1 shows a first embodiment of a timing signal generator, in this case, a frequency synthesizer, as generally designated by numeral 101. A selected or programmed value 103 (e.g., a desired frequency f₀) is input into the frequency synthesizer; depending on embodiment, such a value can be programmed at time of manufacture, in-situ or dynamically; for example, FIG. 1A is intended to encompass both implementations where a selected or programmed frequency is fixed by “fuse” or other assembly-time selection of frequency (e.g., for a specific application), as well as implementations where a programmed digital value is received by frequency synthesizer 103 and loaded into a register, e.g., to dynamically and/or programmably adjust timing signal generation parameters. The timing signal generator produces an output 105, including or more timing signal (e.g., clock) frequencies and/or phases, as dictated by one or more provided and/or programmed values 103. As introduced above, a number of oscillation sources 108, 109 . . . 110 are effectively selected between, for example, by control circuitry 111, which uses one or more control signals 113 to adjust frequency synthesis, as generally represented by numeral 114. These control signals can adjust frequency synthesis circuitry, such as for example, a divider/multiplier filter or other circuit within or outside of the feedback loop of a PLL, or they can adjust circuitry associated with the oscillation sources themselves, depending on embodiment. For example, as indicated by block 115, in one contemplated case, the control circuitry 111 can adjust multiplication/division factors (integer or fractional) within a PLL's feedback loop (e.g., within frequency synthesis circuitry 114) so as to provide control over a frequency generated by a VCO; such an operation, in one embodiment, effectively selects one of the depicted oscillators (Osc. 1-Osc. N) in a manner that picks the lowest phase noise oscillation source as a function of the programmed generation frequency (fp), as referenced by function block 117. Alternatively, it is possible to implement circuits that automatically discriminate between oscillation sources/control frequency generation on the basis of of another performance parameter (e.g., other than phase noise), once again, as a function of generated timing signal frequency (e.g., as represented by the function F{fp}). As denoted by numeral 118, the depicted design effectively provides for in-situ selection of an oscillator that will dominate and/or drive the output(s) 105, for a frequency range where the selected oscillator is best-suited, given the performance criteria of interest. In some embodiments, it is possible for control circuitry 111 to directly control generation by one or more oscillators (Osc. 1-Osc. N), as implied by the presence of dashed-line (optional) control signals 113. As indicated by numeral 119, in one embodiment, optional in-situ or dynamic programming can even be used to select and/or change the performance parameter of interest, e.g., to change how different oscillation sources are discriminated and/or applied.

As noted earlier, one embodiment controls frequency synthesis on a basis where a generated output has a phase noise profile which tracks one of several oscillation sources, as a function of which oscillation source produces the best phase noise parameters for a frequency range of interest. FIGS. 2A-2B are used to help explain the use of multiple PLLs in terms of oscillation source selection and discrimination; these FIGS. will generally be discussed together.

A frequency synthesis circuit or other timing signal generator 201 generates or is provided with a reference frequency (f₀), 203. Conventionally, a PLL 205 might be used to generate a stable output, for example, by driving a VCO (not seen in FIG. 2A) either faster or slower, so as to lock a generated timing signal 206 to the phase and frequency of the reference frequency (f₀), 203. As explained earlier, the loop rate of the PLL 205, represented as point “A” in frequency, causes the signal 206 to track phase noise of the reference frequency (f₀), 203, below point “A” and to track frequency of the VCO above point “A.” FIG. 2B is a very general phase noise plot 251 (log) which shows the effects of this discrimination, i.e., the reference frequency (f₀), 203 has a phase noise profile generally corresponding to curve 253; were it not for the PLL, the phase noise would be expected to progress asymptotically, as denoted by a dashed-line 255. The finite loop rate of the PLL 205 however, effectively causes signal 206 to track the phase noise of its VCO above point “A,” i.e., such that above the loop rate of the PLL 205, the phase noise of signal 206 will instead possess the phase noise characteristics of the VCO, i.e., progressing asymptotically as indicated by dashed-line 257.

In accordance with principles introduced by this disclosure, two or more PLLs can be used, such as a second PLL 207, a third PLL 209 and (as indicated by ellipses 210), potentially other PLLs (e.g., a k^{th} PLL 211), as illustrated in FIG. 2A, so as to effectively select oscillation sources which will dominate an output depending on programmed frequency; in this design, each PLL is designed to have an associated loop rate so as to effect frequency discrimination (and consequent selection of an oscillation source that will dominate one or more generated timing signal outputs φₒᵤₜ₋₁-φₒᵤₜ₋ⱼ) in a manner that will effectively “pick” whichever oscillation source is best given a frequency range of interest. For example, the second depicted PLL 207 can be designed to have a loop rate corresponding to frequency point “B”, where the PLL effectively relies on a VCO (not shown in the FIG.) which produces lower phase noise than is conventional, such as represented by curve 259 in FIG. 2B. In a similar manner, an optional third PLL 209 can be designed to pass phase noise for its PLL (i.e., in a manner corresponding to loop rate “C,” such as represented by phase noise curve 261, and so on, continuing through the k^{th} PLL's loop rate (represented by point “K” and phase noise curve 263. The depicted design thus relies on multiple PLLs (e.g., two or more) so as to cause the one or more generated timing signal outputs φₒᵤₜ₋₁-φₒᵤₜ₋ⱼ to provide substantial improvement in phase noise as a function of which corresponding frequency band (i.e., corresponding to one of the oscillation sources) encompasses the frequency to be synthesized. It is possible to add PLLs and/or oscillation sources which provide phase noise improvement to the left side of plot 251, for example, as indicated by curve 265 and frequency point A′. As noted previously, multiple PLLs can be structured in series, in parallel, in a cascaded or nested manner, or otherwise, depending on specific embodiment. FIG. 2A depicts a series of PLLs for the purposes of illustration and not limitation. It is understood that combinations and permutations of PLLs may be cascaded and nested (as described above and below). Furthermore, as denoted by reference numerals 213, 215 and 217, more than one timing signal can be generated, depending on implementation, and these various signals can be, if suitable for the given implementation, drawn from mid-stage PLLs, such as depicted in FIG. 2A in the case of signal φₒᵤₜ₋ⱼ 217, with optional use of one or more ‘parallel’ PLLs, e.g., per numeral 219.

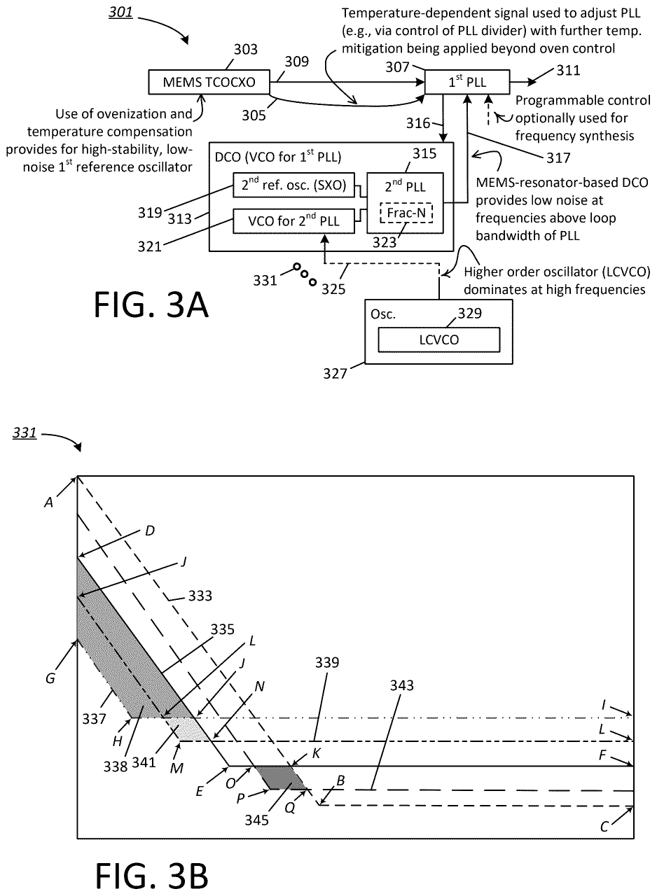

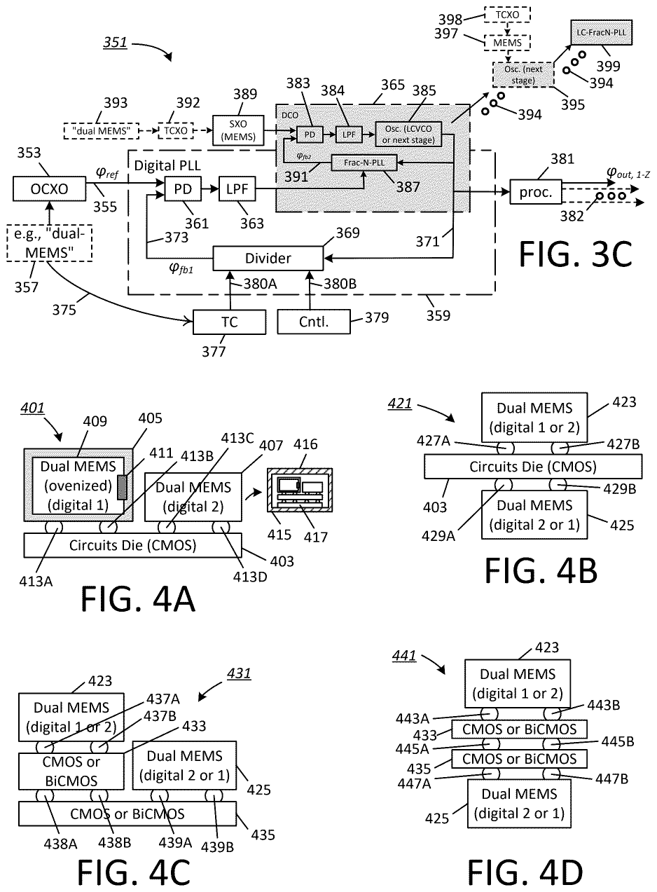

FIG. 3A is an illustrative diagram which shows another embodiment 301 of a timing signal generator that employs some of the principles discussed herein. This timing generator is embodied as a frequency synthesizer/clock generator circuit, e.g., it is designed so as to create, on a selective basis, one or more different frequencies within a range, with a nested-PLL structure being used to effectively select between different oscillation sources depending on the frequency that is to be generated. This embodiment uses a temperature-compensated, oven-controlled oscillator (“TCOCXO”) 303 to generate a highly-stable baseline, reference signal; again, other contemplated embodiments do not require either a TCXO or OCXO for use as this first oscillator. As depicted in the FIG., this particular TCOCXO is based on at least one MEMS resonator; such, however, is also not required for all embodiments. Depending on preference and/or implementation, each MEMS resonator can be a piezoelectric MEMS resonator or an electrostatic MEMS resonator; a mixture of each can be used in multi-resonator designs, if desired.

As is known, resonators are used in electronics to generate an oscillating signal having a frequency, which can vary as temperature changes. Quartz crystals are traditionally used as a resonators in most digital electronic devices, although newer MEMS-resonators are starting to replace the use of quartz crystals, i.e., as these may be fabricated using semiconductor fabrication techniques. The use of oven control of a resonator typically attempts to lock a resonator to a predetermined temperature, in order to mitigate temperature-dependent variation; this is to say, at least in theory, temperature-dependent variation endemic to quartz crystals, MEMS and many other types of resonators, is conventionally thought of as irrelevant if the temperature is not allowed to vary. In a typical “oven-controlled” design (“OCXO”), the resonator is kept in an insulated chamber or “oven” and is heated to, and maintained at a particular set point temperature (e.g., using feedback control); this temperature is typically above the standard temperature operating range of the resonator—for example, if an electronic chip is designed to be fully operative in an ambient temperature range of −40 to +85 degrees Celsius, then an oven-controlled oscillator might keep the resonator at +100 degrees Celsius, and not allow this temperature to vary as the ambient temperature changes (e.g., it is typically easier to heat the resonator than to cool it down). Because oven control typically produces an oscillator output signal that is relatively stable, and does not vary significantly with temperature change, further compensation for temperature variation in many conventional applications is thought to be unnecessary and/or superfluous.

The design illustrated in some of the FIGS. by implementing a “TCOCXO,” however, goes further, and not only maintains a controlled “oven” (i.e., an OCXO), but further, measures temperature of the oven and also applied electronic compensation of resonance frequency variation as function of variation in temperature; generally speaking, this temperature control (TC) can be provided on a front end basis, e.g., via variation of driving signal, or bias voltage adjustment (e.g., for an electrostatic design) and in other cases, this temperature control (TC) can be provided in downstream circuitry, e.g., in a PLL, so as to electronically adjust timing signal frequency as a function of measured temperature.

In the design depicted in FIG. 3A, the latter approach is used. The TCOCXO block 303 includes a chamber (e.g., often but not always a ceramic enclosure), a MEMS die in the chamber, a heating element in the chamber, a temperature sensor, and circuitry that relies on the temperature sensor and the use of feedback to drive the heating element, such that the MEMS resonator always operates at a predetermined temperature. The temperature sensor may either be collocated with the MEMS resonator, i.e., on the MEMS die, or nearby to that MEMS die (e.g., in abutting contact), depending on embodiment. As with some conventional OCXO MEMS resonator designs, the depicted design features a resonating body that is designed to exhibit a cubic relationship between temperature change and change in resonance frequency, with a “turnover temperature,” i.e., a point at which resonance frequency briefly becomes temperature invariant, as the slope of frequency change relative to temperature switches between positive and negative sign. As noted, OCXO resonators are typically designed such that this turnover temperature is necessarily hotter than a normal ambient temperature operating range. In the depicted design, this temperature is typically at least 120 degrees Celsius or greater. MEMS-based resonator OCXO designs typically feature a resonator design that places the turnover temperature well above the normal temperature operating range, and the OCXO's heat control circuitry keeps the resonator heated exactly to this temperature, because at this operating point, the MEMS resonator is relatively insensitive to minor fluctuations in temperature, i.e., the resonator's temperature coefficient of frequency (“TCF”) is approximately zero within a narrow range about the turnover temperature. The depicted TCOCXO block 303 further outputs a temperature-dependent signal 305, which is used to provide temperature concentration in downstream circuitry. In the illustrated embodiment, this more specifically occurs within the feedback path of the first or outermost PLL loop 307, where temperature compensation (“TC”) is applied together with control over frequency synthesis to control a divider. The feedback loop is used to lock a controlled oscillator-based output to the reference frequency, i.e., from TCOCXO block 303. In a conventional PLL, the controlled oscillator would typically be a voltage controlled oscillator (“VCO”), but in the depicted embodiment, this VCO is effectively replaced by a second PLL loop 315 (i.e., an inner PLL loop), which, in this case, implements a digitally-controlled oscillator (“DCO”) 313. The first PLL loop 307 thus outputs a digital signal 316 to control this DCO 313, which in turn, provides an oscillation signal 317 back to the first PLL loop 307. The first PLL loop 307 thus controls frequency increase or decrease by the DCO in an attempt to achieve phase lock between the first frequency reference signal 309 and an oscillation signal derived from signal 317 (e.g., a divided version of this signal, as controlled in part by temperature-dependent signal 305). Note that this configuration also further relaxes design constraints for the TCOCXO block 303 and its resonator(s) relative to conventional OCXO designs, i.e., operation of the resonator at the turnover point becomes less critical, as programmed coefficients that respond to temperature-dependent signal can be used to compensate for temperature-dependent variations. Such coefficients, learned and programmed product-by-product (e.g., at the factory), also provide a convenient mechanism for compensating manufacturing process corners. In the depicted design, therefore, it becomes possible to operate the oven at an arbitrary temperature, e.g., 15 degrees Celsius above the normal operating temperature range of the electronic device. For example, if an electronic device containing the timing generator is to be operated within a rated temperature range of 0° to +70° Celsius (“C”), −40° to +85° C., −55° to +125° C., or a different temperature range, the OCXO can be designed to heat the resonator to maintain a temperature of approximately +85° C., +100° C. or +140° C., or about 15° above whichever temperature range is used, and the resonator can also optionally be designed such that its turnover point coincides with that temperature.

In certain embodiments, the TCOCXO block 303 uses two MEMS resonators. In such a design, a first one of the two MEMS resonators is typically designed so as to have a resonance frequency which is temperature-invariant throughout a temperature range of interest, while the second of the two MEMS resonators produces a resonant frequency that varies strongly, but ideally linearly, with temperature change. The first of the two MEMS resonators is used as the basis for an oscillator output signal 309, while both of the resonators are used to implement a temperature sensor. In such a design, as temperature varies, the respective frequencies of the two resonators either converge or diverge, enabling a precise determination of temperature. Further, since resonator frequencies produce a signal that repeats thousands-to-millions of times per second, the frequency can be digitally quantified, the ratio of the two frequencies can be used to provide a highly-granular digital measurement of temperature. In one configuration, a MEMS die (i.e., with two MEMS resonators) outputs two sinusoidal signals, respectively representing resonance frequency of the particular resonator; the ratio of these two signals is then used by downstream circuitry, e.g., on a circuits die, to identify temperature, and to control the oven so as to be temperature-invariant. Note that the two MEMS resonators do not need to be designed to operate at exactly the same frequency; in this regard, the two resonators are typically designed to operate in the kilohertz (“kHz”) to megahertz (“MHz”) frequency range, with one of the two resonators deliberately designed to differ in baseline resonance frequency from the other by approximately +/−10%. For example, in one contemplated design, one of the two MEMS resonators can be designed to operate in the range of approximately 25-50 MHz, e.g., at a baseline resonance frequency of 35 MHz, while the other resonator is designed to operate at about 90-95% of this frequency, e.g., at a baseline resonance frequency of 32 MHz. It should be observed that these specific characteristics are not required for all implementations.

Note again that an OCXO, a TCXO, a TCOCXO and/or use of a MEMS resonator are not required for all embodiments, e.g., some embodiments use simply a conventional OCXO (e.g., with a quartz crystal or other resonating structure) to generate a baseline reference frequency which is provided as a reference to a nested-PLL structure; such a structure provides a stable, baseline frequency that performs well in combination with a use of an electronic VCO to generate higher frequencies. Depending on embodiment, control can also be provided to adjust signals derived from the baseline reference frequency for further temperature compensation (“TCOCXO”). For embodiments that do implement a MEMS resonator-based design, a “dual-MEMS” resonator design is also not required for all embodiments, e.g., other types of temperature sensors (including without limitation, one based on a transistor, thermistor, diode or other structure), can also be used. Furthermore, in some designs, the temperature sensor is not on the same die or substrate as the resonator.

With temperature of the oven being controlled so as to remain at a constant temperature, the timing signal 309 of the embodiment of FIG. 3A is highly-stable, i.e., it maintains a well-defined frequency notwithstanding change in ambient environment (e.g., the internal or external environment of an electronic device). However, to enhance this stability, the depicted OXCO further outputs a temperature-dependent signal 305, which, as mentioned, is provided to the first PLL (i.e., outer PLL loop) 307 for temperature compensation. Note that, as is common with PLL designs, the depicted PLL 307 also relies on a phase detector (“PD”) and a low pass filter (“LPF”), as well the aforementioned DCO 313, a feedback path and a divider, to then produce a further timing signal 311 as an output; the PD, LPF and the feedback path/divider are not separately shown in FIG. 3A, although example of these elements will be presented in some of the other FIGS.

The DCO 313 has a general configuration that is shown in expanded detail in FIG. 3A. As noted, this controlled oscillator of the first PLL 307, i.e., the DCO, is provided by a second PLL 315 (i.e., a second, inner PLL loop), which is controlled as function of signal 316. This second PLL 315 relies on a frequency reference signal from a second oscillator (“SXO”) 319, and it uses its own controlled oscillator 321 (i.e., which can either be a further PLL loop or an electronic VCO, depending on embodiment). The second PLL 315 attempts to lock a signal produced from this controlled oscillator 321 to a frequency reference signal from the second oscillator (“SXO”) 319, and in so doing, effectively implements a filter which tracks noise from SXO 319 for mid-range frequencies and oscillator 321 for higher frequencies. The second oscillator 319 can also optionally be based on a MEMS-resonator design, and optionally, a temperature-compensated (“TC”) or “dual-MEMS” design. As should be observed therefore, in some embodiments, a total of three, four, or more, MEMS resonators can be used (e.g., two in the TCOCXO, and two in the SXO). As is indicated by the FIG., the second PLL has a divider which can optionally be a fractional-N divider, as referenced by numeral 323. As denoted by arrow 325, the controlled oscillator 321 is, in some manner, dependent on an electronic VCO (i.e., a LCVCO 329); in embodiments that use three or more PLL loops, the controlled oscillator can be structured to be similar in design to inner PLL loop 315, i.e., instantiating oscillator 321 as an additional PLL loop which itself has a controlled oscillator 327 that is dependent on LCVCO 329. Ellipses 331 denote that further PLL/oscillator stages can also be used, as desired. In this event, the fractional-N divider is optionally pushed down to the innermost PLL (e.g., the feedback loop of the third PLL). In a similar manner, the electronic VCO or other oscillator suited for very high frequency generation can be being relegated to the innermost PLL loop.

The effect of these design features is explained in reference to FIG. 3B, which plots frequency stability/phase noise as a function of output timing signal frequency, in a graph generally designated by numeral 331. Note that various noise profiles are represented in the FIG. by lines having different dash-patterns, which will be referred to below for purposes of illustrating benefits that can be obtained by the structures which were introduced above. It should first be noted that these various noise profiles are shown for purposes of discussion as a series of straight lines, but it is noted that, in practice, are in curves with gradually changing slopes that very roughly conform to the line patterns indicated in FIG. 3B.

A PLL having a conventional VCO-based design is generally represented by curve 333, tracing points A-B-C; as is seen, such a PLL typically performs with low phase noise at high frequencies, but with high instability when applied to lower frequency timing signal generation. By contrast, a conventional MEMS-resonator-based oscillator has phase noise characteristics generally indicated by curve 335, i.e., tracing points D-E-F. In a system which relies on a MEMS-resonator-based oscillator with a VCO-based PLL, output signal noise characteristics generally trace path D-E-K-B-C, i.e., with the PLL generally passing phase noise of the MEMS-resonator-based oscillator at PLL frequencies below the loop rate of the PLL (represented by point K), and with phase noise of the VCO dominating higher frequencies. Ovenizing this PLL generally improves frequency stability of the MEMS-based oscillator, and consequently results in a noise plot which is shifted to the left, relative to line 335. For example, the use of a MEMS-based TCOCXO in accordance with embodiments discussed herein generally results in a noise plot tracking line 337, i.e., tracing path G-H-I in the FIG. By using a nested-PLL structure, as indicated above, the system can be effectively designed to switch between oscillation sources for purposes of frequency stability, e.g., a noise plot can be made to generally track points G-H-J-E-K-B-C in the FIG. As is seen by a shaded parallelogram DJHG, this results in a substantial phase noise improvement relative to a design only having a single PLL loop, i.e., particularly at low frequencies. At PLL frequencies below a loop tracking rate of the “first” or outer PLL loop, represented by point J in the FIG., the lower phase noise of the TCOCXO dominates; at PLL frequencies between points J and K in the FIG., phase noise of a traditional MEMS-based-resonator oscillator dominates (e.g., from second oscillator SXO from FIG. 3A). Finally, as with the conventional design, the phase noise of a traditional electronic VCO dominates the output of the nested-PLL structure at higher frequencies, above a frequency represented by the location of point K in the FIG. Note that, if desired, additional PLL loops and associated oscillation stages can be added; for example, using the principles discussed, an optional first additional PLL loop can be used to switch in an oscillator having noise characteristics generally represented by line 339; the same PLL-loop bandwidth considerations just discussed can be applied here, i.e., to eliminate phase noise within a second shaded area 341 (represented by parallelogram JNML), and to result in a noise plot generally tracing points G-H-L-M-N-E-K-B-C. Such an additional PLL loop could instead be designed for higher loop bandwidths, per line-plot 343, i.e., to eliminate phase noise associated with a third shaded area 345 (represented by parallelogram KQPO); and, naturally, it is possible to do both of these things together, i.e., have four or more nested PLL loops, and a nested-PLL output generally tracking the lowest phase noise levels represented by FIG. 3B, throughout the frequency range of interest.

By lowering phase noise generally and by providing a timing signal generator design with stable frequency characteristics throughout the entirety of a frequency range of interest, the present embodiments provide designs particular suitable for the requirements of some of the newer digital platforms, especially those requiring a wide range of frequency synthesis. For example, it was earlier mentioned that newer devices typically require generation of many timing signals, often at very different frequencies. Frequency synthesizers often are designed to generate a baseline frequency, which is then multiplied up and/or divided down, so as to produce any timing rate desired, from very low to very high frequencies. As noted earlier, conventional circuit designs often result in excessive phase noise at some point in the desired frequency spectrum. By promoting a design which generally minimizes phase noise throughout the frequency spectrum of interest, embodiments presented herein address the problems introduced earlier, and provide for greater frequency-stability throughout a large range of frequencies, e.g., from sub-hertz (<1 Hz) to tens of gigahertz (“GHz”).

FIG. 3C illustrates another embodiment 351 of a timing signal generator capable of meeting these goals. As seen in the FIG., an oven-controlled oscillator (“OCXO”) 353 is used to generate a first frequency reference signal 355 (labeled φ_{ref} in the FIG.). Per dashed-line (optional) box 357, the OCXO is also optionally a MEMS-based oscillator, seen in the FIG. to be premised on a “dual-MEMS” design, although this also is not required for all embodiments. The frequency reference signal 355 is provided to a fully-digital PLL 359. This digital PLL 359 includes a digital phase detector (“PD”) 361, a digital low pass filter 363, a digitally-controlled oscillator (“DCO”) 365, a feedback path 367, and a divider 369 in the feedback path. The divider receives an output signal 371 from the DCO, and either increases or reduces frequency of this signal, dependent on control of the divider 369; the divider provides a signal 373 for comparison by the phase detector (“PD”) 361 (this feedback signal 373 is labeled φ_{fb1} in the FIG.). Control over the divider 369 in this embodiment is performed in dependence on each of a signal from temperature compensation circuitry and a control input 379. As noted, the temperature compensation can be omitted in some embodiments, and it is also possible for control 379 (e.g., frequency synthesis control) to be injected elsewhere into the system. The PD 361 compares phase of the OCXO output 355 with phase of the feedback signal 373, and provides impetus to the DCO to either increase or decrease the frequency of the signal 371, dependent on whether the feedback signal 373 lags or leads frequency reference signal 355. Thus, as production of higher frequencies is demanded (e.g., as a function of control block 379), the division denominator is increased, which forces the DCO 365 to produce a higher frequency output. Conversely, when a lower frequency is called for, the division is decreased (i.e., feedback frequency is increased), which in turn causes the DCO to decrease the frequency of its output. As noted earlier, the divider 369 (in this embodiment) is also driven based on a temperature signal 375 from the OCXO, such that the feedback signal 373 pushes the DCO frequency, either slightly higher or lower, in order to offset temperature fluctuations. In this regard, temperature correction (“TC”) circuitry 377 generates a digital control signal for use in controlling the divider, by looking up correction coefficients or other temperature compensation, so as to apply the appropriate amount of correction. It should be noted that temperature compensation can take the form of circuitry which implements an analog or digital polynomial, or that simply retrieves configuration values from a look-up table in a manner, or in some other manner, indexed according to variation in signal 375. Because the DCO represents a fully digital design in this embodiment, control signal(s) 380A/380B can be digitized, if not already in digital form.

The signal from the DCO 371, is then conditioned for output by processing circuitry 381, and is optionally used to generate any number of timing signals, for output, e.g., at fixed or programmably-variable frequency and/or phase separation, depending on embodiment; this is represented by ellipses 382 and timing signal acronyms φ_{1-Z}. These optional timing signal outputs φ_{1-Z} can have represent common or dissimilar harmonics, as desired; that is, in one embodiment, multiple timing signals are output which have a predetermined phase and/or frequency relationship, and in another embodiment, parameters for one or more of these timing signal outputs (e.g., each timing signal) can be independently set.

The DCO 365 is, once again, implemented as the inner loop of a nested-PLL structure, as was the case for the embodiment introduced by FIG. 3A. In the design of this FIG., an inner PLL loop within DCO 365 is seen to include an analog phase detector (“PD”) 383, an analog low pass filter (“LPF”) 384, a controlled oscillator 385 for the second PLL loop, and a fractional-N divider 387 in a feedback path of the loop. An output of the LPF 363 from the digital (outer) PLL loop 359 is used to control the feedback path of this inner PLL loop; this has the effect of driving frequency production by the DCO based on a noise profile for the second oscillator (“SXO”) 389, with phase noise from the controlled oscillator 385 dominating for higher frequencies. In this regard, the analog PD 385 compares phase of a second frequency reference signal 390 from SXO 389 with a feedback signal 391 from the fractional-N-divider, in a manner where adjustment of the divider speeds up or slows down the rate of the inner PLL's feedback loop, i.e., to effectuate this selection. In this embodiment, the SXO is seen to also be rooted in use of a MEMS-resonator, which as indicated in the FIG., can optionally be a temperature-compensated design (“TCXO”) and/or a dual-MEMS design, as per numerals 392 and 393. If a TCXO design is used, a temperature sensor can be implemented using the same or a different architecture as was described above for OCXO 353, e.g., it can be “dual-MEMS” structure or it can be based on use of a thermistor, a diode, transistor, dual-MEMS, etc., to measure temperature. Note that it is within the level of ordinary skill in the art to select components as necessary to achieve frequency stability and/or phase noise and/or power requirements for a particular application.

As indicated by text within controlled oscillator 385, the controlled oscillator can, once again, optionally be an electronic VCO (e.g., a LCVCO). The depicted design thus effectively employs each oscillator, i.e., the OCXO, the SXO, and the LCVCO for the frequency range where that oscillator is most efficient for purposes of frequency stability. As indicated by ellipses 394, it is possible to have more than two PLL loops, i.e., with another one or more inner PLL loops used to provide controlled oscillator 385, each having its own reference oscillator 395; once again, any one or more of these can optionally be based on a MEMS resonator architecture 397 and/or a TCXO architecture 398. In the depicted architecture, because the electronic VCO has the most suitable phase noise characteristics for higher frequency synthesis from among those options presented, the electronic VCO is advantageously relegated to the innermost loop, as indicated by reference numeral 399. Should another type of oscillator work best at ultrahigh frequencies, then that oscillator can be used as the controlled oscillation source of the inner loop of the nested PLL structure, with the electronic oscillator moved elsewhere in the PLL loop hierarchy.

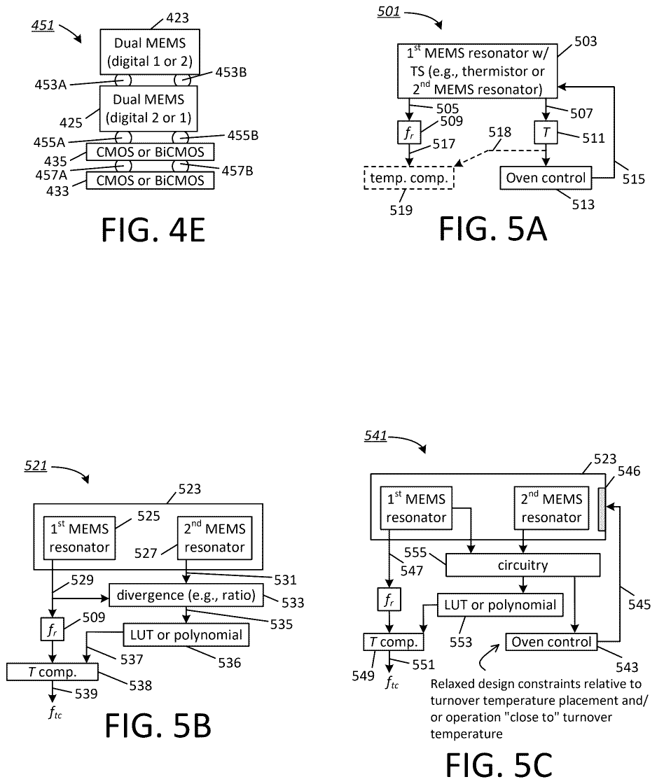

As was referenced earlier, some embodiments provide specific die configurations which can be used in combination with the various structures introduced above. FIGS. 4A-4E are used to describe some of these configurations. It is firstly noted that these various FIGS. show inter-die electrical connections and mounts in the form of solder bumps; the use of solder bumps in the FIGS, however is to be understood as a graphical proxy for any type of electrical connection, e.g., wire bonds or other connection types can be used in some embodiments, and/or a mixture of connection types including solder bumps can also be used. It is also noted that the structures seen in FIGS. 4A-4D can optionally be further mounted on some type of substrate and/or can be packaged, enclosed or sealed, such that they are sold as an integrated, self-contained device (e.g., as a packaged, frequency synthesizer and/or clock generator integrated circuit (“IC”). Such mountings and/or enclosures are deemed optionally included in the configurations represented by FIGS. 4A-4E.

FIG. 4A shows a first arrangement 401 having a circuits die 403, a first MEMS die 405 and a second MEMS die 407. The respective MEMS dies can mount resonators in internal cavities, e.g., in a hermetically-sealed environment; these dies and their associated resonators can optionally represent different process technologies (e.g., one can be a piezoelectric resonator, another can be electrostatic, lidded and vent-released, “single-MEMS”/“dual-MEMS,” ceramic/plastic enclosed, and/or bonded lid designs, and so forth). In other embodiments, the same or similar process technology and/or architecture can be used for each MEMS die. The first MEMS die 405 in this embodiment is seen to include an insulator to provide thermal insulation, e.g., first die features an oven 409 having an internal heating element 411 for purposes of oven control. Note that while these elements of an OCXO design are illustrated only for first MEMS die 405, they can be replicated for any MEMS die discussed herein (e.g., any MEMS die seen in any of FIGS. 4A-E and/or the other FIGS.). The thermal isolation represented by numeral 409 can be any suitable material, although it is noted that, in some embodiments, a ceramic material is used to provide thermal isolation. In interests of brevity, depiction of oven particulars is omitted from the rest of these FIGS. Each of MEMS dies 405/407, in turn, is seen to be directly mounted to/electrically interconnected with circuits die 403, e.g., via one or more of solder bump connections 413A, 413B, 413C and 413D. The circuits die, in this embodiment, provides much of the processing circuitry for operating the various MEMS devices as well as for providing the nested-PLL structure described earlier.

Thus, whereas conventional wisdom might imply that a complex multi-IC configuration would be needed for a cascaded PLL architecture, typically in separately-packaged and independently-mounted structures, in some present embodiments, this level of complexity can be reduced dramatically by combining one or more of (1) drive/sense circuitry for respective oscillators on a common circuits die (e.g., die 403) or small numbers of such dies, (2) circuitry for multiple PLL loops on a common circuits die (e.g., analog and digital PLLs as described for some embodiments herein), (3) one or more PLL loops of the nested-PLL structure described herein together with sense/drive circuitry for one or more MEMS resonators on a common circuits die, and/or (4) oven control and/or temperature compensation circuitry, as described herein, with any permutation of these various circuit elements. As a nonlimiting example, consonant with the depiction of FIG. 4A, it is possible to have circuitry for each of these things mingled together on a common circuits die 403, such that the MEMS dies 405/407 can be directly mounted to this common, single circuits die, to provide for a compact footprint and/or a high degree of integration. As noted earlier, and as with any of the other embodiments discussed herein, such a device (e.g., “die stack”) can optionally be packaged and sold as a standalone device, e.g., a single, packaged integrated circuit (“IC”) having multiple dies, as denoted by graphic 415; such a device can optionally be encased in plastic 416 and/or otherwise packaged as a unitary structure, e.g., on a common substrate or lead frame, as represented by numeral 417.

FIG. 4B shows an alternate configuration 421, that is, where MEMS dies are mounted above and below circuits die and/or some common substrate 403, directly or indirectly through other dies. Here, optional use of packaging and/or additional substrates are omitted for purposes of brevity, although it is noted that with each embodiment discussed herein, structures can be packaged together, e.g., in a common IC die stack, as was just indicated. As represented in the FIG., a first MEMS die 423 can be either of the MEMS resonator dies/systems introduced earlier (e.g., OXCO or SXO), as represented by the vernacular “digital 1 or 2” appearing in the FIG., while a second MEMS die 425 can be the other of these two. The first MEMS die 423 is seen to be attached to the circuits die and/or substrate 403 via a first set of solder bump mounts 427A-427B, while the second MEMS die 425 is mounted by a different set of mounts 429A-429B, e.g., on an opposite side of circuits die 403. Note that while two such solder bump mounts are illustrated, in practice, a larger number are present (and are occluded in this view). For example, a typical OCXO MEMS die might feature six or more pins, e.g., one for a drive impetus, one for a sensed resonator output, one for a resonator bias voltage, one for oven control (e.g., a pin to receive an analog and/or digital oven control signal, or multiple such signals), and if needed, pins to establish voltage supply rails (e.g., V_{dd} and/or Vₛₛ/ground, as pertinent to the design). A typical SXO die might have only three pins, such as for V_{bias} and for sense or drive signal interface, e.g., in the case of an electrostatic MEMS resonator design. To promote a compact footprint, each die is, however, advantageously designed to use a minimal number of pins and/or connections for mechanical support and electrical interface, although the number of such pins/connections will depend on implementation (e.g., as just implied, in various embodiments, each resonator can be based on an electrostatic, piezoelectric, two-port and/or other designs). As with others of the features discussed herein, the mechanical and/or electrical interconnection options discussed relative to FIG. 4B can be used for any of the configurations seen in FIGS. 4A-4E, or indeed, for the other figures described herein.

FIG. 4C shows yet another configuration 431, this time with the use of two circuits dies or substrates, i.e., 433 and 435. As expressly indicated in the FIG., either of these substrates can be CMOS or BiCMOS based circuits; for example, it may be more efficient for some manufacturing processes to have a first die which is dedicated to BiCMOS circuitry (e.g., fabricated using a process technology specific to a BiCMOS die) and a second die which is dedicated to a different process technology (e.g., a specific CMOS process technology). In the depicted configuration, for example, the first of the MEMS dies 423 in one embodiment is an OCXO resonator die, with the BiCMOS die providing support circuitry, such as charge pump and heater control circuitry for this OXCO resonator die, and the second of the MEMS dies 425 can represent a non-OXCO resonator design, for example, supported purely by CMOS circuitry. In such a configuration, both BiCMOS and CMOS circuitry are used to support the OCXO implementation, such that first MEMS die 423 is directly mounted to a BiCMOS die (433) and through that die to CMOS die (435), in a stacked arrangement, via solder bump mounts 437A-437B and 438A-B; the second MEMS die is seen to be directly mounted to the CMOS die (435), via solder bump mounts 439A-B. While this configuration implies that BiCMOS circuitry is used only for first MEMS die 423, in fact, either or both dies can be supported by circuitry on either die, with electrical interconnections performed using either die as an intermediary (as pertinent to the application), and conversely, each circuits die 433/435 can feature circuitry supporting one or both MEMS dies 423/425. As implied by FIG., use of any BiCMOS or CMOS technology is optional, i.e., both depicted circuits dies can be CMOS dies or BiCMOS dies in a given embodiment, and both dies can represent the same or different process technologies in another. It is also possible to have more than two circuits dies and more than two MEMS dies, e.g., with the MEMS dies sharing circuitry on a given circuits die, as appropriate, and with three or more circuits, resonator, or other dies present.

FIGS. 4D-4E each show additional “dual-circuits-dies” configurations, generally labeled 441/451 in the respective FIG. Each of these configurations also features two MEMS dies, which can each be designed to support an OCXO, TCXO or XO configuration, as appropriate, but here, all four dies 423/425/433/435 are shown together in a stacked configuration. In FIG. 4D, the MEMS dies 423/425 are stacked on either side of the circuits dies. These various dies are seen in FIG. 4D to be interconnected using respective solder bump mounts 443A-443B, 445A-445B and 447A-447B. In FIG. 4E, the MEMS dies 423/425 are stacked on top of each other (e.g., die 425 can have through silicon vias that permit each of these dies to be stacked directly on top of one another); the respective dies in this FIG. are interconnected using solder bump mounts 453A-453B, 455A-455B and 457A-457B. Although not illustrated specifically here, it also possible to interleave dies, e.g., MEMS/circuits/MEMS/circuits, such being a special case of the embodiment depicted in FIG. 4B. As these examples demonstrate, nearly any permutation or combination of die arrangements can be used to achieve a compact footprint and/or integrated device, e.g., all facilitated using the novel techniques presented by this disclosure.

Note also that although two MEMS dies are indicated in each of FIGS. 4A-4E that any one of these dies can have more than one MEMS resonator (e.g., any given one or more of these dies can be made to support a “dual-MEMS” resonator design and can consequently feature two, three or more resonators, e.g., in the same or different cavities or chambers within the die). Also pertinent to some of the embodiments discussed above, a given MEMS die can also have other circuitry, for example a built-in heating element (as illustrated in FIG. 4A), a temperature sensor, electrostatic discharge structures, and/or other elements present on that same MEMS die.

FIG. 5A is a diagram used to exemplify an embodiment 501 of an OCXO; this embodiment features a MEMS die 503 having both a MEMS resonator and a temperature sensor. A first MEMS resonator is used to provide an oscillating signal 505, which represents sensed resonance frequency of the resonator. A second MEMS structure forms part of a temperature sensor (“TS”); as noted elsewhere herein, such a sensor generally can be a second MEMS resonator (i.e., operating in tandem with the first MEMS resonator), a MEMS or other type of thermistor, a diode, a transistor or another structure. The MEMS die 503 therefore also outputs a second signal 507 which is temperature dependent, and which varies according to an operating temperature of the first MEMS resonator (i.e., preferably, the temperature sensor is in close proximity with this primary MEMS resonator, such that the signals 505 and 507 represent characteristics produced by exactly the same temperature). As indicated by numerals 509 and 511, these signals are processed, as appropriate, to generate a reference frequency signal (fᵣ) 517 and a temperature signal (T). The temperature signal is provided as feedback to oven control circuitry 513, and used to drive the oven so as to maintain a constant temperature, as previously described (i.e., per control arrow 515). Because the oven is controlled such that the resonator is always operated at or near a constant temperature, the reference frequency signal 517 is relatively stable. As indicated by dashed line structures 518 and 519, the temperature signal can also optionally be used for further temperature compensation of the output reference frequency signal (e.g., thereby implementing a TXOCXO); this will be further exemplified below.

FIG. 5B shows an embodiment 521 of a TCXO based on use of a “dual-MEMS” architecture. A MEMS die 523 includes a first MEMS resonator 525 and a second MEMS resonator 527; one of these resonators is designed to operate in a manner which is relatively temperature-invariant and/or at a resonant frequency that is easily correctable relative to temperature (i.e., a “temperature-flat” resonator), while the second of these resonators is designed to have a temperature that varies strongly, but linearly, with temperature change (i.e., a “temperature-sensing” resonator). In this regard, it is well-known to those having skill in the art how to fabricate various types of MEMS resonators capable of serving as these devices (or as other resonators described herein); see, as nonlimiting examples, U.S. Pat. Nos. 9,774,313, 9,712,128 and 10,696,547. As described therein, MEMS resonators and/or a MEMS resonator and other type of temperature sensor may be manufactured side-by-side on the same chip, in a manner that promotes thermal coupling between the two; techniques are used to specifically engineer resonator operating parameters, i.e., with design variables such as resonator dimensions (size, shape, thickness, length, width, etc.), relationship between those dimensions to underlying axis/axes of single crystal silicon, doping impurities and relative concentration(s), use of other materials in the design, and many other variables structures so as to provide for precise engineering of temperature-dependent performance. There exist no shortage of MEMS resonator designs in the art, and existing, working examples of dual-MEMS resonators and their related designs may be observed in the working products and from the datasheets of SiTime Corporation, generally available from www.sitime.com. In one embodiment, one or more of the resonators depicted in FIG. 5B (and/or the other FIGS.) may be electrostatic resonators, and in another embodiment, one or more of these may be piezoelectric. Despite the name “temperature-sensing,” signals 529/531 from each of the MEMS resonators are used together to calculate a measure of absolute temperature. Circuitry 533 receiving these signals calculates the divergence of these frequencies (e.g., by taking their ratio, or by other means), to produce an output signal 535; this output signal directly represents sensed absolutely temperature. This signal 535 is then provided to a lookup table (i.e., to index programmed temperature correction factors) or is otherwise applied to circuitry to obtain a temperature correction signal 537. This temperature correction signal is then provided to temperature-compensation circuitry 538, which corrects the resonance frequency signal (fᵣ) 509 from the temperature-flat resonator, in order to produce a temperature-compensated frequency output signal (f_{tc}) 539. Note that either of fᵣ and/or f_{tc} can be used as a PLL's frequency reference signal, depending on design. The temperature correction circuitry is typically downstream from the circuitry that drives the resonator, e.g., in a downstream PLL, though this is not required for all embodiments; for example, as noted earlier, there are temperature compensation schemes that call for adjusting adjust a drive signal used to excite a resonator (i.e., that performs correction in the “sustain circuitry”), as well as designs that adjust bias voltage of an electrostatic resonator to mitigate frequency variation as a function of temperature change. Other designs/configurations are possible too.

As noted earlier, some embodiments use a “dual-MEMS” resonator design in the OCXO, while others can also or instead use a “dual-MEMS” architecture as the basis for the SXO, or indeed, third or greater order stages, to generate a frequency reference. In other embodiments, a “dual-MEMS” architecture is not used and, e.g., a MEMS resonator plus thermistor (or other temperature sensor) design can be used, as was discussed relative to FIG. 5A. Finally, in still other embodiments, conventional oscillator structures (e.g., quartz crystal, electronic, etc.) can be used for one or more PLL loops to generate a PLL reference signal.

FIG. 5C shows an example 541 of a “dual-MEMS” design that is also ovenized, and therefore can be used as the basis for the TCOCXO of FIG. 1A (or other embodiments discussed herein). As was the case with the design seen in FIG. 5B, a MEMS die 523 once again has two or more MEMS resonators, for example, positioned side-by-side, on a common die, in a manner that promotes thermal shorting between “TF” and “TS” resonators. Oven control circuitry 543 generates a control signal 545 which is applied to a heating element 546 to regulate oven temperature. This design produces a reference frequency output (fᵣ) 547 that exhibits little-to-no temperature-dependent variation, i.e., because the oven temperature is not allowed to vary to any significant degree. Nevertheless, circuit-based temperature compensation is also applied, as represented by a temperature compensation block 549; the result, as with some of the examples presented above, is a temperature-compensated frequency output signal (f_{tc}) 539. A control signal is generated by the circuitry to control frequency compensation; this control signal can be analog or digital, based on a lookup table (“LUT”) and/or polynomial, and it can be produced as a function of divergence of resonant frequencies of the two MEMS resonators, e.g., by circuitry 555. As indicated by a text legend appearing in the FIG., because further temperature compensation is applied to a frequency reference signal produced by the oven, this relaxes design and/or operation requirements for the oven, e.g., it is not as critical to place the oven and/or either resonator precisely at the turnover temperature; optionally, the depicted first MEMS resonator is designed so as to have a resonator turnover temperature at about fifteen degrees Celsius above the maximum expected operating temperature, and optionally, the oven control circuitry 543 is configured to use this temperature as a setpoint for the oven. As this discussion implies, in some embodiments, the oven temperature can be set to be either above, or below, the turnover temperature of the resonator used for frequency generation. In practice, at the time of manufacture of each specific product (or in some cases, for a product class generally), the product is probed while the heating element 546 is being cycled through various temperatures, and this is used to generate (1) programmable parameters for the oven control circuitry 543, i.e., which are then programmed into that circuitry and/or supporting memory, and (2) frequency compensation and/or filter parameters, including for example, data for the LUT and/or polynomial circuitry, with resultant data also being programmed into circuitry or supporting memory. Advantageously, the design includes a non-volatile memory (“NVM”), not seen in this FIG., which is used for this purpose.

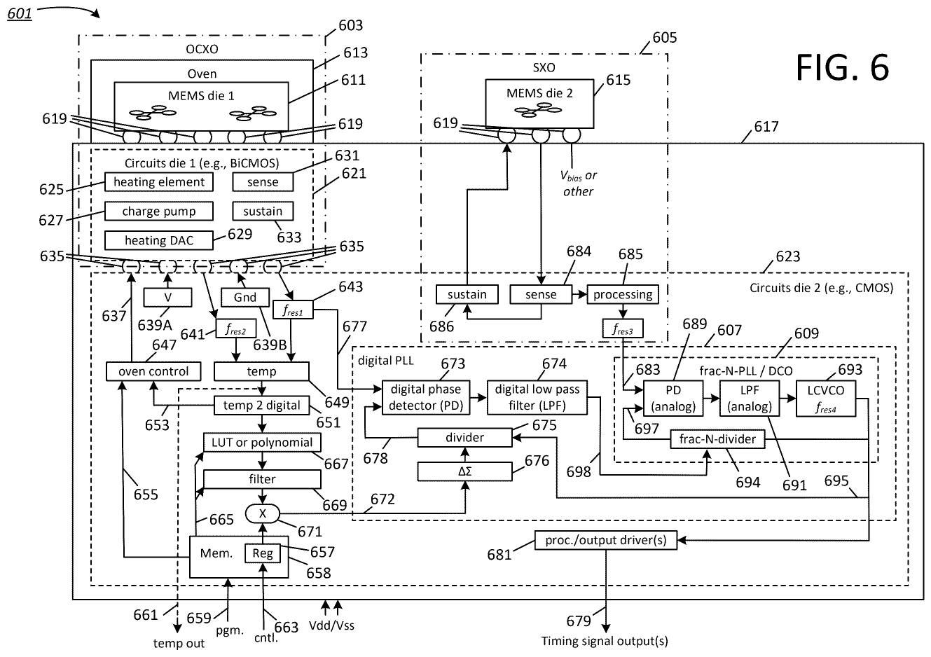

FIG. 6 shows a still more detailed embodiment 601, which illustrates some of the unit and die relationships in a particular design. As with some of the embodiments discussed earlier, this design is seen to be predicated on the use of an OCXO 603, a SXO 605 and a nested-PLL structure, comprising in this embodiment, two PLL loops, including a first, outer (digital) PLL loop 607 and a second, inner (fractional-N, analog) PLL loop 609. These design elements are generally denoted in dashed lines to indicate their various constituent components (e.g., which elements are associated with the OCXO), including circuitry, which may reside on one or more different dies. FIG. 6 also shows the juxtaposition of different die configurations, including a configuration having first MEMS die 611 (i.e., with one or more resonators within an oven, e.g., within a ceramic ovenized chamber) 613, and a second MEMS die 615. The first MEMS die 613 in this embodiment is seen to be of a dual-MEMS design, were each resonator is structured as a set of four rings born at respective ends of a cross structure, while the second MEMS die 615 is seen to have a single MEMS resonator of similar structure. In other embodiments, different resonator designs can be used. These various MEMS dies in one configuration are each directly mounted to a CMOS die 617, e.g., by solder bump mounts 619; these solder bump mount depictions in the FIGS. should once again be viewed as symbolic, e.g., these depictions proxy wirebond and other conventional types of connections, in addition to, or instead of, the depicted use of solder bumps. Note that FIG. 6 also references a second, alternative configuration as well; that is, instead of using a single circuits die 617, two circuits dies can instead be used 621 and 623, including a first circuits die 621 that has BiCMOS elements (e.g., used to control the OXCO) and a second die 623 dedicated to CMOS elements used to support all of the OCXO 603, the SXO 605, first (outer) PLL loop 607 and second (inner) PLL loop 609, and other circuitry. Other die configurations can also be used, as previously discussed.

As is seen to the left-hand side of the diagram, elements used to support the OCXO, and that form a part thereof, include a heating element 625, a charge pump 627 to drive the heating element, a heating digital-to-analog converter (“DAC”) 629, sense circuitry 631, and sustain circuitry 633. As indicated by the optional presence of a BiCMOS die 621, these elements can optionally be configured as BiCMOS elements. Alternatively, as indicated by numeral 617, these elements can be implemented in CMOS (e.g., as part of a single die 617). If a dedicated circuits die for the OCXO (or other oscillator type) is used, as represented by numeral 621, then such a circuits die can be mounted to die 623 (or a common substrate) via a set of solder bump mounts 635. The heating element 625 is used for oven control during normal operation; it can also be used in some embodiments for thermal characterization (e.g., to identify and program oven control data, temperature compensation data, and/or other operational parameters, i.e., as part of a calibration operation performed in the factory, post-manufacture, post-packaging and/or in-situ), and/or to tune/trim one or both resonators, for example, using joule-heating processes that change resonator-dopant characteristics, and thereby adjust resonant frequency; see, e.g., U.S. Pat. No. 9,712,128. In some embodiment, the heating element 625 can comprise multiple discrete heating devices, for example, one for oven control, one for thermal cycling, and one for each resonator for joule-based heating and for trim/tune of the individual corresponding resonator; other configurations and combinations of these structures are clearly also contemplated. The charge pump 627 can be used to generate high heat levels for any of these processes. The heating DAC 629 receives a digital serial or parallel word signal (e.g., via solder bump mounts 635), which it uses to address each heating device individually (if desired), and also to generate variable amounts of heat, as appropriate. Finally, the sense and sustain circuitries 631 and 633, respectively, are used to sense resonant frequency of each resonator on die 611, and to excite the resonators to resonant motion.

If an OCXO circuits die is used, the depicted solder bump mounts 635 once again provide a minimal pin set to drive the OCXO; as depicted, these will typically include at least one digital signal 637, for control of the heating element, one or more voltage supply rails 639A/B (i.e., labeled “V” and “GND” in the FIG.), and frequency outputs 641 and 643 for the respective resonators (labeled “fᵣₑₛ₂” and “fᵣₑₛ₁”). Some embodiments can also use a controllable or adjustable bias voltage (e.g., in the case of electrostatic resonator designs). In this regard, the CMOS elements on die 617 or die 623 (depending on configuration) include a set of circuits used to support the OCXO, including oven control circuitry 647, circuitry 649 to identify temperature from the resonator signals, and a temperature-to-digital converter 651. In the depicted embodiment, the oven control circuitry 647 controls the heating element 625, including each constituent heating device as appropriate, by generating digital signals which are then sent to the heating DAC 629; these control signals can be parallel digital signals or sent via a serial interface (e.g., one or more pins) depending on configuration. Once again, the oven control circuitry controls the amount of heating, as pertinent to applications supported by the OXCO, including set point temperature maintenance during a normal operating mode, thermal cycling for purposes of device characterization, and/or trim/tune processes, as discussed above. Logic that is part of the oven control circuitry, as with other elements discussed herein, can include dedicated special purpose hardware, or a combination of general purpose hardware circuits and instructional logic, as referenced elsewhere herein. The temperature identification circuitry 649, as noted elsewhere herein, performs division of the two frequency signals “fᵣₑₛ₁” and “fᵣₑₛ₂,” to identify an absolute temperature, and the temperature-to-digital circuitry 651 then converts this absolute temperature to a set of digital control values 653, which are supplied to the oven control circuitry 647 as feedback, so as to obtain precise absolute temperatures in the oven. As denoted by arrow 655, the oven control circuitry 647 also receives values from onboard memory 658 (e.g., a NVM), representing learned oven control parameters, for use in normal operations and optional configuration (e.g., for use in thermal cycling/device characterization and/or tune/trim processes). If desired, a signal representing absolute temperature can optionally be provided for external output, as indicated by numeral 661 at the bottom-left of the FIG. (e.g., for provision to a microprocessor or other elements of a digital device or system, for downstream use/application). The memory 658 also receives programming, during a calibration mode, of learned temperature compensation data (e.g., via external pin 659) which is then used to control further temperature compensation provided by the TCOCXO design. This same pin or a different pin 663 can also be used to receive a signal representing active frequency selection, which the system stores in a register 657; this register can be implemented using any suitable memory technology, including without limitation, random access memory (“RAM”), the mentioned-NVM, or a different technology. For active temperature compensation of frequency output by the OCXO, a LUT or polynomial is implemented using learned TC parameters from memory 658, with temperature compensation data then being passed through filter 669; temperature compensation is then combined with the register-stored active frequency selection parameters, in block 671, to develop a first control signal 672 to control the digital (outer) PLL loop 607.

The digital (outer) PLL loop 607 includes a digital phase detector (“PD”) 673, a digital low pass filter (“LPF”) 674, a digitally controlled oscillator (which is provided by second PLL loop 609), divider 675 and a delta-sigma modulator 676. The PD 673 receives its frequency reference signal from the OCXO as signal 677 (fᵣₑₛ₁), as well as a feedback signal 678, the latter being generated by divider 675. Briefly, the output of the PD 673, as filtered, controls the DCO (fractional-N, inner PLL loop 609) to increase or decrease generated frequency as a function of whether signals 677 and 678 are in synch. The divider 675 can be an integer divider and/or a fractional divider. This divider is controlled responsive to signal 672 so as to provide both frequency scaling and temperature correction. When low frequencies are desired, the divider effectively provides division by a large amount, i.e., such that feedback signal 678 is slowed; the outer PLL 607 therefore tries to slow the DCO/inner PLL loop 609 to synch these two, resulting in a lower frequency at timing signal output pin 679. Conversely, when a high level of frequency output is desired, divider 675 uses a small value, and the outer PLL loop then tries to speed up the DCO/inner PLL loop 609. When the timing signal output 679 is at low frequencies, phase noise (and frequency stability) of the OCXO will be passed through and will dominate the timing signal output (i.e., so as to have the ultra-stable characteristics of the TCOCXO), but as this frequency is increased, the digital (outer) PLL loop 607 will result in domination of this output by phase noise of the DCO (i.e., the inner PLL loop 609). Note that the timing signal output is conditioned by processing circuitry 681, which contains suitable drivers for off-chip/off-device transmission, e.g., through pin 679; also note that while a single pin is discussed in this text, the use of numeral 679 contemplates that differential and/or other signal formats can also be provided for (i.e., by respective pins).

The SXO 605, as noted previously, provides a frequency reference input signal 683 (fᵣₑₛ₃) for use by the inner (i.e., analog, second) PLL loop 609; this analog loop is digitally-controlled, i.e., it serves as the DCO. The SXO includes sense circuitry 684 and processing circuitry 685 to generate signal 683 as an output, and sustain circuitry 686, which is used to maintain resonant motion of the MEMS resonator(s) in the second MEMS die 615. The electrical connections to this die include drive and sense signals, as well as a voltage bias signal (e.g., once again, in the case of an electrostatic resonator design); as indicated earlier, the second MEMS die 615 can alternatively rely on a piezoelectric resonator design. As depicted in the FIG., this support circuitry for the SXO is typically on the primary circuits die (i.e., 617 or 623), such that this die in this embodiment includes at least some support circuitry for each of the OXCO 603, the SXO 605, for oven control and temperature compensation, and for each of the PLL loops 607 and 609. In one embodiment, the SXO is designed to produce a significantly higher frequency than the OCXO. For example, in one embodiment, 35 MHz and 32 MHz resonators can be used as the temperature flat (“TF”) and temperature sensing (“TS”) resonators of the dual-MEMS design, while the SXO can feature a resonator designed to produce an oscillating signal at 75-80 MHz.

The inner PLL loop 609 is seen in the FIG. to have an analog phase detector (“PD”) 689, an analog low pass filter (“LPF”) 691, an electronic VCO 693 (e.g., a LCVCO), and a fractional-N divider 694. The analog PD 689 receives reference signal 683 from the SXO 605 and attempts to drive the electronic VCO (through LPF 691), increasing or decreasing the frequency of signal 695, until a feedback signal 697 from the fractional-N divider 694 is in synch with the reference signal 683. The fractional-N divider 694, in turn, is controlled by the variable frequency output 698 from the outer (digital) PLL loop 607. The fractional-N divider is consequently controlled so as to increase or decrease the frequency of signal 695 as a function of the output the digital LPF 674 from the first (outer) PLL loop 607.

At low frequencies, phase noise of the OCXO will dominate frequency output 679, as mentioned; at higher frequencies, phase noise of the DCO (inner PLL loop 609) begins to dominate. The DCO phase noise will track phase noise of the SXO for frequencies below the loop rate of the innermost PLL loop 609, and then track phase noise of the electronic VCO 693 at higher frequencies. The design of the depicted circuit is therefore such that, the nested-PLL structure, configured as illustrated, effectively switches between three or more different oscillators, according to which has the best frequency stability characteristics at a given clock generation frequency.

Returning briefly to FIG. 3B, it should be noted that the effect of this operation is to lower phase noise (i.e., increase frequency stability) through a wide range of operating frequencies. The depicted circuit design effectively causes the timing generator of FIG. 6 to roughly trace phase noise pattern G-H-J-E-K-B-C, seen in that FIG. Where 35 MHz and 78 MHz frequency reference signals are generated (i.e., as per the exemplary resonator frequencies discussed above), points J and K will roughly correspond to these two frequencies. A skilled designer, applying these principles, can therefore optimize frequency stability across a wide range of frequency production, e.g., by engineering MEMS (and/or other) resonators, as desired, and by using a switching structure as discussed, so as to engineer the sources of phase noise at specific frequencies of a given timing signal generator design. As a non-limiting example, if a designer hypothetically wanted to place points J and K of FIG. 1B at 5 MHz and 125 MHz, the resonators are simply engineered to obtain these results; as noted above, this can be done in a relatively straightforward manner where MEMS resonators are used as a basis for at least part of the design. As noted earlier, by optionally including additional PLL loops in a nested-PLL structure, where and as desired, further benefits in overall phase noise may be achieved, e.g., to roughly trace pattern G-H-L-M-N-E-O-P-Q-B-C where four PLL loops are used; again, these may be engineered as desired to customize phase noise/frequency stability in a manner deemed best to suit a specific application.

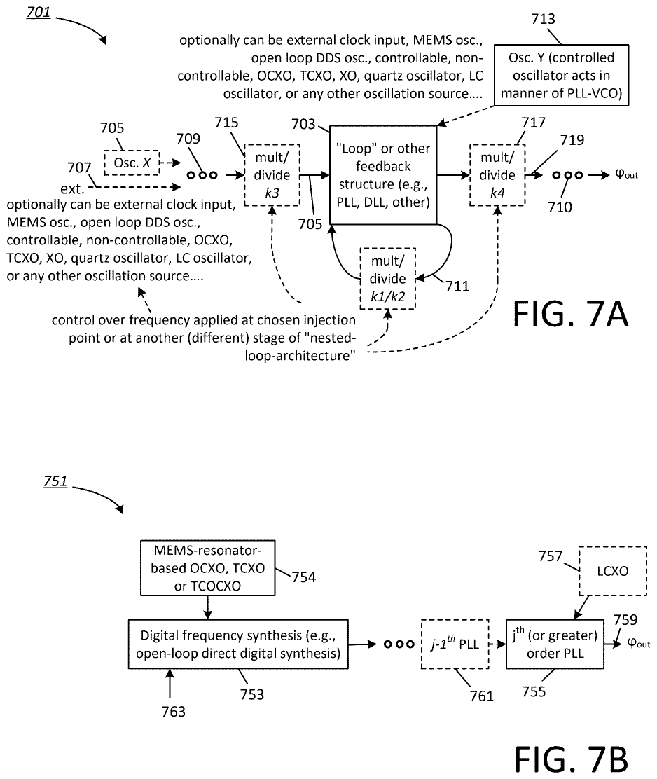

FIG. 7A shows architectures featuring a device 701 where multiplication and/or division factors can be applied at various points in relation to a given-stage PLL 703; for example, the depicted PLL can be any of the PLLs in any of the embodiments discussed thus far. As indicated previously, a reference frequency signal 705 is used as an input to the PLL. In one contemplated variation, this reference frequency signal 705 can be generated by an onboard oscillator “X” 705 (for example, which can optionally be based on a single- or dual-MEMS resonator structure and/or a DDS circuit, as discussed earlier). In other embodiments, the reference frequency signal can be generated off-device (e.g., off-chip) and provided as an input (e.g., via a pin or other die-attach mechanism). As denoted by ellipses numerals 709 and 710, there can be other circuits which receive, process and/or provide these signals, for example, one or more “upstream” PLLs and/or one or more “downstream” PLLs (e.g., in a series, parallel, cascade or other configuration). Irrespective of whether such additional PLLs are present, the depicted PLL 703 includes a feedback loop 711 which optionally provides for multiplication/division of a generated frequency, e.g., generated by oscillator “Y” 713 (which is a controllable oscillator which acts as the VCO for the PLL); as seen in the FIG., the optional multiplication/division factor is represented by the quantity k1/k2, denoting that any values can be used for scaling of a feedback signal, whether unitary, integer, fractional or otherwise. As referenced by optional structures 715 and 717 (representing multiplication/division coefficients k3 and k4, which once again, can be integer coefficients, fractional coefficients or otherwise) can be used to provide PLL and/or frequency control outside of the feedback path. The depicted PLL generates an output 719 which can either serve directly as a generated frequency output (φₒᵤₜ) or can be processed by further downstream circuitry.

FIG. 7B shows an embodiment 751 that uses at least one MEMS based resonator as part of an open-loop direct digital frequency synthesis (“DDS”) circuit 753. It is noted that, optionally, non-MEMS-based resonators can be used and/or the MEMS-based design can be implemented as an OCXO, TCXO, TCOCXO, and/or as a dual-MEMS structure, as referenced textually by block 754 of the FIG.). In the depicted design, open-loop DDS is used to generate a reference frequency signal (which typically performs well at relatively low frequency); the VCOs of downstream PLLs are driven to attempt to match the frequency of the timing signal generated by the DDS circuit 753, with the result that the loop rates of the various PLLs provide cut-offs that cause a generated output (759) to only track phase noise of the DDS circuit 753 for low frequencies. Advantageously, in some optional embodiments, an output of the open-loop DDS circuit 753 is ultimately provided to a PLL 755 which has an LC oscillator 757 as its VCO. It will be recalled from the discussion of earlier embodiments that LC oscillators typically perform well when applied to high frequency generation and, in the depicted design, the loop bandwidth of the PLL 755 is designed such that the (better) phase noise characteristics of the LC oscillator dominate the output (φₒᵤₜ, 759) when the depicted circuit is used for high frequency generation. Note that there can optionally be one or more intermediate stage PLLs 761 (that is, positioned in between the open-loop DDS circuit 753 and the “j^{th} PLL” depicted in the FIG., e.g., which can feature the use of additional oscillators). Note that control over generated frequency (e.g., provided by a register value) is injected, in this embodiment, directly into the DDS circuit 753 (e.g., as opposed to being injected into the feedback path of one of the PLLs). It is alternatively, possible to use the open-loop DDS circuit 753 downstream of one or more other optional “upstream” PLLs and/or to employ the open-loop DDS circuit 753 as an oscillation source that will serves as the VCO for such an upstream PLL (for example, as implied in FIG. 7A).

Reflecting on the foregoing, what has been described is a timing signal generator having improved frequency stability characteristics. This timing signal generator in a typical embodiment is implemented as a frequency synthesis and/or clock generator device, e.g., as a packaged integrated circuit assembly, or otherwise. Such a device can optionally include one of the die configurations described earlier, or optionally, a variant thereof. The device can be packaged and/or enclosed/encapsulated, or otherwise structured. When implemented as a frequency synthesizer, the timing signal generator can achieve improved frequency stability characteristics by using a series, parallel, cascaded and/or nested-multi-PLL structure. In one embodiment, the multiple PLLs are arranged for example in a manner such that the loop bandwidth of each PLL in the nested loop structure selects a different oscillation source depending on the output frequency selected of the device. Three or more oscillation sources can be switched between in terms of oscillator performance characteristics which dominate a generated output timing signals, given any performance parameter of interest; in specific embodiments discussed above, the performance parameter of interest can be lowest phase noise for a frequency range of interest. In some embodiments, one or more of these oscillation sources can be based on one or more MEMS resonators; the use of MEMS resonators in such a design promotes a high degree of integration, as MEMS resonators can be manufactured consistent with semiconductor fabrication processes, and the entire system can be produced as a small stack of dies, i.e., in a manner amenable to implementation as a single, multi-die IC (e.g., again, encapsulated or otherwise). Any combination and/or permutation of resonator designs can be used for any given stage, depending on design goals or implementation: a MEMS resonator; a quartz crystal resonator; an electronic resonator; an LC resonator; a single-MEMS resonator; a dual-MEMS resonator; a design having more than two resonators, whether configured in series, parallel or otherwise; a temperature-compensated oscillator (“TCXO”); an oven-controlled oscillator (“OCXO”); a temperature-compensated, oven-controlled oscillator (“TCOCXO”); an electrostatic resonator; a piezoelectric resonator; and indeed, any resonator and/or oscillator design now known or hereinafter created, again, in observance of the principles and objectives set forth herein. As a non-limiting example of these principles, in one embodiment of techniques described herein, a cascaded structure of two, three, four or more resonators are used, with a multi-PLL structure, as described; in a specific implementation, active temperature compensation can be used in one of the inner PLL loops, that is, without regard to whether such compensation is used in the outermost loop, and without regard to whether a OCXO or MEMS-resonator design is used as the outermost loop. These nonlimiting example once again illustrate that the various features described herein are not required for all embodiments.

The circuits and techniques described above may be further constructed using automated systems that fabricate dies and/or integrated circuits, and may be described as instructions on non-transitory media that are adapted to control the fabrication of such integrated circuits. For example, the components and systems described may be designed as one or more integrated circuits, or a portion(s) of an integrated circuit, based on design control instructions for doing so with circuit-forming apparatus that controls the fabrication of the blocks of the integrated circuits. The instructions may be in the form of data stored in, for example, a computer-readable medium such as a magnetic tape or an optical or magnetic disk or other non-transitory media as described earlier. Such design control instructions typically encode data structures or other information or methods describing the circuitry that can be physically created as the blocks of the integrated circuits. Although any appropriate format may be used for such encoding, such data structures are commonly written in Caltech Intermediate Format (“CIF”), Calma GDS II Stream Format (“GDSII”), or Electronic Design Interchange Format (“EDIF”), as well as high level description languages such as VHDL or Verilog, or another form of register transfer language (“RTL”) description. Those of skill in the art of integrated circuit design can develop such data structures from schematic diagrams of the type detailed above and the corresponding descriptions and encode the data structures on computer readable medium. Those of skill in the art of integrated circuit fabrication can then use such encoded data to fabricate integrated circuits comprising one or more of the circuits described herein.

In the foregoing description and in the accompanying drawings, specific terminology and drawing symbols are set forth to provide a thorough understanding of the present technology. In some instances, the terminology and symbols may imply specific details that are not required to practice the technology. For example, although the terms “first” and “second” have been used herein, unless otherwise specified, the language is not intended to provide any specified order but merely to assist in explaining elements of the technology. In some instances, the terminology and symbols may imply specific details that are not required to practice those embodiments. The terms “exemplary” and “embodiment” are used to express an example, not a preference or requirement. Moreover, although the technology herein has been described with reference to particular embodiments, it is to be understood that these embodiments are merely illustrative of the principles and applications of the technology. It is therefore to be understood that numerous modifications may be made to the illustrative embodiments and that other arrangements may be devised without departing from the spirit and scope of the technology.

As noted earlier, various documents have been incorporated into this disclosure by reference. The definitions provided by this disclosure are to control (i.e., predominate over any definitions in the incorporated by reference documents) in the event of any inconsistency or conflict, implicit or otherwise, with the meaning of terms as used in this document.

Various modifications and changes may be made to the embodiments presented herein without departing from the broader spirit and scope of the disclosure. Features or aspects of any of the embodiments may be applied, at least where practicable, in combination and/or permutation with any other of the embodiments or in place of counterpart features or aspects thereof, and each is to similarly be considered “optional” as to any embodiment and/or combination/permutation. Accordingly, the features of the various embodiments are not intended to be exclusive relative to one another, and the specification and drawings are to be regarded in an illustrative rather than a restrictive sense.

1. A timing signal generator, comprising:
a first oscillator (FXO);
a second oscillator (SXO);
a first phase-locked loop (PLL) to receive an output of the FXO and to generate a first signal therefrom; and
a second PLL to receive an output of the SXO and to generate a second signal therefrom, wherein the second PLL comprises an oscillation source that is at least partially dependent on an electronic voltage controlled oscillator (VCO), and wherein the second PLL comprises a divider that is controlled in dependence upon the first signal;
wherein the timing signal generator is to output a timing signal dependent on the second signal.

2. The timing signal generator of claim 1 wherein the FXO comprises at least one microelectromechanical systems (MEMS) resonator and at least one structure to serve as a temperature sensor.

3. The timing signal generator of claim 2 wherein:
the at least one microelectromechanical systems (MEMS) resonator comprises two MEMS resonators;
the FXO is to generate the first signal dependent on a resonance frequency of a first one of the two MEMS resonators;
the at least one structure to serve as a temperature sensor is embodied as the two MEMS resonators; and
the timing signal generator further comprises circuitry to generate a temperature-dependent signal as a function of divergence of respective resonant frequencies of the two MEMS resonators.

4. The timing signal generator of claim 3 wherein:
the FXO is an oven-controlled oscillator (OCXO); and
the OCXO comprises a heating element and circuitry to control the heating element, using the temperature-dependent signal, to urge temperature of the two MEMS resonators toward a first temperature.

5. The timing signal generator of claim 4 wherein the timing signal generator comprises circuitry to correct a temperature-dependent variation of the resonance frequency using the temperature-dependent signal, to thereby implement a temperature-compensated OCXO (TCOCXO).

6. The timing signal generator of claim 2 wherein:
the divider is a second divider;
the FXO is to generate the output of the FXO dependent on a resonance frequency of the at least one MEMS resonator;
the first PLL comprises a first divider;
the timing signal generator further comprises circuitry to generate a temperature-dependent signal dependent on an output of the temperature sensor; and
the first divider is to be controlled dependent on the temperature-dependent signal, to thereby implement a temperature-compensated oscillator, based on the SXO.

7. The timing signal generator of claim 6 wherein:
the timing signal generator comprises a first die and a second die;
the FXO is on the first die; and
circuitry of the first PLL and the circuitry of the second PLL are each on the second die.

8. The timing signal generator of claim 1 wherein the SXO comprises at least one microelectromechanical systems (MEMS) resonator.

9. The timing signal generator of claim 8 wherein the SXO also comprises at least one structure to serve as a temperature sensor, to sense a temperature of the at least one MEMS resonator.

10. The timing signal generator of claim 9 wherein:
the at least one microelectromechanical systems (MEMS) resonator comprises two MEMS resonators;
the SXO is to generate the output of the SXO dependent on a resonance frequency of a first one of the two MEMS resonators;
the at least one structure to serve as a temperature sensor is embodied as the two MEMS resonators;
the timing signal generator further comprises circuitry to derive a temperature-dependent signal as a function of divergence of respective resonant frequencies of the two MEMS resonators; and
the timing signal generator comprises circuitry to correct a temperature-dependent variation of the resonance frequency using the temperature-dependent signal, to thereby implement a temperature-compensated oscillator (TCXO), based on the second oscillator.

11. The timing signal generator of claim 1 wherein the electronic VCO is a LC voltage controlled oscillator (LCVCO).

12. The timing signal generator of claim 1 wherein:
the SXO is a first SXO and the divider is a first divider;
the oscillation source further comprises a second SXO and a third PLL, the third PLL to receive an output of the second SXO, the third PLL having a second divider controlled according to the second signal, the third PLL having an oscillator;
the oscillator of the third PLL is the electronic VCO; and
the timing signal output by the timing signal generator is dependent on an output of the third PLL.

13. The timing signal generator of claim 1 wherein:
the first PLL has a first loop rate;
the second PLL has a second loop rate; and
the first PLL and the second PLL are part of a nested-PLL structure, such that phase noise of the timing signal output by the timing signal generator is dominated by phase noise of the FXO at a first frequency of the timing signal, less than the first loop rate, by phase noise of the SXO at a second frequency of the timing signal, between the first loop rate and the second loop rate, and by phase noise of the electronic VCO at a third frequency of the timing signal, above the second loop rate.

13. The timing signal generator of claim 1, embodied as a frequency synthesizer, wherein:
the timing signal generator comprises a programmable register;
the first PLL also comprises a divider which is at least partially controlled dependent on content of the programmable register; and
the timing signal output by the timing signal generator has a frequency that is dependent on the content of the divider.

14. The timing signal generator of claim 1 wherein:
the timing signal output by the timing signal generator is a first timing signal;
the timing signal generator is to output a second timing signal; and
the second timing signal and the first timing signal differ from one another in terms of at least one of phase or frequency.

15. The timing signal generator of claim 1 wherein:
the timing signal generator comprises a first die and a second die;
at least one of the FXO and the SXO comprises a MEMS resonator;
the MEMS resonator is on the first die; and
circuitry of the first PLL and circuitry of the second PLL are each on the second die.

16. The timing signal generator of claim 1 wherein:
the timing signal generator comprises a first die, a second die and a third die;
each of the OCXO and the SXO comprises at least one MEMS resonator;
the at least one MEMS resonator of the OCXO is on the first die;
the at least one MEMS resonator of the SXO is on the second die; and
circuitry of the first PLL, circuitry of the second PLL, circuitry to drive the at least one MEMS resonator of the OCXO, and circuitry to drive the at least one MEMS resonator of the SXO are each on the third die.

17. A timing signal generator, comprising:
a first oscillator, wherein the first oscillator is an oven-controlled oscillator (OCXO), and wherein the first oscillator comprises at least one microelectromechanical systems (MEMS) resonator and at least one structure to serve as a temperature sensor;
a second oscillator (SXO);
a first phase-locked loop (PLL) to receive an output of the OCXO and to generate a first signal therefrom, wherein the first PLL has a divider; and
a second PLL to receive an output of the SXO and to generate a second signal therefrom, wherein the second PLL comprises an oscillation source that is at least partially dependent on an electronic voltage controlled oscillator (VCO), and wherein the second PLL comprises a divider that is controlled in dependence on the first signal;
wherein the timing signal generator is to output a timing signal dependent on the second signal.

18. The timing signal generator of claim 17 wherein:
the timing signal generator further comprises circuitry to generate a temperature-dependent signal dependent on an output of the temperature sensor, wherein the divider of the first PLL is to be controlled responsive to the temperature-dependent signal, to thereby implement a temperature-compensated OCXO (TCOCXO).

19. The timing signal generator of claim 18 wherein:
the at least one microelectromechanical systems (MEMS) resonator comprises two MEMS resonators;
the OCXO is to generate the first signal dependent on a resonance frequency of a first one of the two MEMS resonators;
the at least one structure to serve as a temperature sensor is embodied as the two MEMS resonators;
the circuitry to derive the temperature-dependent signal is to do so as a function of divergence of respective resonant frequencies of the two MEMS resonators; and
the OCXO comprises a heating element and circuitry to control the heating element, dependent on the temperature-dependent signal, to urge temperature of the two MEMS resonators toward a first temperature.

20. The timing signal generator of claim 19 wherein:
the timing signal generator comprises a first die and a second die;
the OCXO is on the first die; and
circuitry of the first PLL and circuitry of the second PLL are on each the second die.

21. The timing signal generator of claim 17 wherein the SXO also comprises at least one microelectromechanical systems (MEMS) resonator.

22. The timing signal generator of claim 21 wherein the SXO also comprises at least one structure to serve as a temperature sensor, to sense a temperature of the at least one MEMS resonator of the SXO.

23. The timing signal generator of claim 21 wherein:
the timing signal generator comprises a first die, a second die and a second die;
the at least one MEMS resonator of the OCXO is on the first die;
the at least one MEMS resonator of the SXO is on the second die; and
circuitry of the first PLL, circuitry of the second PLL, circuitry to drive the at least one MEMS resonator of the OCXO, and circuitry to drive the at least one MEMS resonator of the SXO are each on the third die.

24. A timing signal generator, comprising:
a first oscillator, wherein the first oscillator is an oven-controlled oscillator (OCXO), and wherein the first oscillator comprises at least one first microelectromechanical systems (MEMS) resonator and at least one structure to serve as a temperature sensor;
a second oscillator (SXO), wherein the first oscillator comprises at least one second MEMS resonator;
a first phase-locked loop (PLL) to receive an output of the OCXO and to generate a first signal therefrom, wherein the first PLL has a divider;
circuitry to generate a temperature-dependent signal dependent on an output of the temperature sensor, wherein the divider of the first PLL is to be controlled responsive to the temperature-dependent signal, to thereby implement a temperature-compensate OCXO (TCOCXO); and
a second PLL to receive an output of the SXO and to generate a second signal therefrom, wherein the second PLL comprises an oscillation source that is an electronic voltage controlled oscillator (VCO), and wherein the second PLL comprises a divider that is controlled in dependence on the first signal;
wherein the timing signal generator is to output a timing signal dependent on the second signal.

25. The timing signal generator of claim 24 wherein the electronic VCO is a LCVCO.
